(19) United States
(12) Patent Application Publication
(10) Pub. No.: US 2026/0371911 A1
(43) Pub. Date: Nov. 19, 2026

(54) ELECTRONIC DEVICE AND OPERATION METHOD THEREOF

(71) Applicant: SEMICONDUCTOR ENERGY LABORATORY CO., LTD., Atsugi-shi, Kanagawa-ken (JP)

(72) Inventors: Ryo HATSUMI, Hadano, Kanagawa (JP); Hisao IKEDA, Zama, Kanagawa (JP); Daiki NAKAMURA, Atsugi, Kanagawa (JP); Tomotaka NISHIMURA, Kawasaki, Kanagawa (JP)

(21) Appl. No.: 19/144,125

(22) PCT Filed: Jan. 8, 2024
(86) PCT No.: PCT/IB2024/050137

§ 371 Date: Jun. 27, 2025

(30) Foreign Application Priority Data
Jan. 13, 2023 (JP) 2023-003469

(51) Int. Cl. H10K 59/80; G04G 9/10

(52) U.S. Cl. CPC H10K 59/8793; G04G 9/10; H10K 59/878; H10K 59/879

(57) ABSTRACT

An electronic device that is small and has high visibility is provided. A watch-type electronic device includes a display panel and an optical device which are placed in a region surrounded by a case and a bezel, and one component such as a reflective polarizing plate of the optical device is fixed to the bezel. By rotating the component fixed to the bezel, the reflective action and transmissive action of light in the optical device are changed, enabling switching between a mode in which display on the display panel is seen from a distance and a mode in which display on the display panel is seen in proximity.

### TECHNICAL FIELD

One embodiment of the present invention relates to an electronic device and an operation method thereof.

Note that one embodiment of the present invention is not limited to the above technical field. The technical field of one embodiment of the invention disclosed in this specification and the like relates to an object, a method, or a manufacturing method. Alternatively, one embodiment of the present invention relates to a process, a machine, manufacture, or a composition of matter. Accordingly, more specific examples of the technical field of one embodiment of the present invention disclosed in this specification include a semiconductor device, a display device, a liquid crystal display device, a light-emitting apparatus, a lighting device, a power storage device, a memory device, an imaging device, an operation method thereof, and a manufacturing method thereof.

Note that in this specification and the like, a semiconductor device generally means a device that can function by utilizing semiconductor characteristics. A transistor and a semiconductor circuit are embodiments of semiconductor devices. In addition, in some cases, a memory device, a display device, an imaging device, or an electronic device includes a semiconductor device.

### BACKGROUND ART

Smartwatches have been widely used as wearable devices. In addition, goggles-type devices and glasses-type devices have been developed as electronic devices for virtual reality (VR), augmented reality (AR), and the like.

Examples of a display device that can be used for these devices include, typically, a display device including a liquid crystal element and a display device including an organic EL (Electro Luminescence) element, a light-emitting diode (LED), or the like.

A display device including an organic EL element does not need a backlight that is necessary for a liquid crystal display device; thus, a thin, lightweight, high-contrast, and low-power display device can be achieved. For example, Patent Document 1 discloses an example of a display device using an organic EL element.

### REFERENCE

### Patent Document

[Patent Document 1] Japanese Published Patent Application No. 2018-107444

### SUMMARY OF THE INVENTION

### Problems to be Solved by the Invention

A smartwatch is small, can access a variety of information, and is highly convenient, but its display portion is often 2 inches or less in diagonal or diameter since it is a device to be worn on the arm. Thus, the text size needs to be small so that a large amount of information can be displayed at a time, which leads to a problem of poor visibility.

An electronic device used for VR, AR, or the like is a type of wearable devices and can provide a very large amount of information such as images with high visibility. Meanwhile, the device is relatively large as a wearable device, and entails a challenge of troublesomeness of being worn on the head.

Thus, an object of one embodiment of the present invention is to provide an electronic device which is small and has good visibility. Another object is to provide an electronic device capable of switching between a distant-viewing mode and a proximate-viewing mode. Another object is to provide an electronic device which is small and lightweight and can be easily attached to or detached from the human body. Another object is to provide a novel electronic device. Another object is to provide an operation method of the above electronic devices.

Note that the description of these objects does not preclude the existence of other objects. One embodiment of the present invention does not have to achieve all these objects. Note that other objects will be apparent from the description of the specification, the drawings, the claims, and the like, and other objects can be derived from the description of the specification, the drawings, the claims, and the like.

### Means for Solving the Problems

One embodiment of the present invention relates to an electronic device which is small and has good visibility.

One embodiment of the present invention is an electronic device of a watch-type, including a case, a bezel, a display panel, and an optical device, in which the display panel and the optical device are placed in a region surrounded by the case and the bezel, light emitted from the display panel can be emitted through the optical device, a first component included in the optical device is fixed to the bezel, and rotating the bezel enables switching between a first mode in which display on the display panel is seen from a distance and a second mode in which display on the display panel is seen in proximity.

The electronic device includes a first circular polarizing plate, a half mirror, and a second circular polarizing plate, the half mirror is provided between the first circular polarizing plate and the second circular polarizing plate, the half mirror has a curved surface with a concave on the second circular polarizing plate side, and the second circular polarizing plate is provided on the bezel side.

The first circular polarizing plate includes a linear polarizing plate and a first retardation plate, and the second circular polarizing plate can include a second retardation plate and a reflective polarizing plate. It is preferable that the reflective polarizing plate be the first component.

It is preferable that the half mirror be placed between a second component and a third component, and a difference between a refractive index of the second component and a refractive index of the third component be less than or equal to 0.3.

It is preferable that a surface of the second component on a side opposite to a side with the half mirror and a surface of the third component on a side opposite to a side with the half mirror be each a plane.

In the above, it is preferable that the rotation angle of the bezel be 90°.

It is preferable that the display panel include an organic EL element.

Another embodiment of the present invention is a method for operating an electronic device, which is a watch-type electronic device including a display panel, in which the electronic device is capable of switching between a first mode enabling distant viewing and a second mode enabling proximate viewing. In the first mode, drive is performed in which an image signal is input to some pixels included in the display panel, and in the second mode, drive is performed in which an image signal is input to every pixel included in the display panel.

Switching between the first mode and the second mode can be performed by rotating a component of the optical device fixed to a bezel.

### Effect of the Invention

According to one embodiment of the present invention, an electronic device with a small size and high visibility can be provided. An electronic device capable of switching between a distant-viewing mode and a proximate-viewing mode can be provided. An electronic device with a small size and lightweight that can be easily attached to or detached from a body can be provided. A novel electronic device can be provided. An operation method of any of the above electronic devices can be provided.

Note that the description of these effects does not preclude the existence of other effects. One embodiment of the present invention does not have to have all of these effects. Other effects can be derived from the description of the specification, the drawings, and the claims.

### BRIEF DESCRIPTION OF THE DRAWINGS

FIG. 1 is a diagram illustrating an electronic device.

FIG. 2A is a diagram illustrating how an electronic device is viewed in a distant mode. FIG. 2B is a diagram illustrating an example of display of the electronic device in the distant mode.

FIG. 3A is a diagram illustrating how an electronic device is viewed in a proximate mode. FIG. 3B is a diagram illustrating an example of display of the electronic device in the proximate mode.

FIG. 4A and FIG. 4B are diagrams each illustrating an optical device.

FIG. 5A to FIG. 5I are diagrams each illustrating a form of components included in an optical unit.

FIG. 6A is a diagram illustrating an electronic device. FIG. 6B is a diagram illustrating an optical device.

FIG. 7A is a diagram illustrating an electronic device. FIG. 7B is a diagram illustrating an optical device.

FIG. 8A to FIG. 8C are diagrams each illustrating an optical device.

FIG. 9A to FIG. 9E are diagrams each illustrating a display device.

FIG. 10A to FIG. 10C are diagrams each illustrating a structure example of a display panel.

FIG. 11A and FIG. 11B are diagrams each illustrating a structure example of a display panel.

FIG. 12A to FIG. 12F are diagrams each illustrating a structure example of a pixel.

FIG. 13A to FIG. 13C are diagrams each illustrating a form of driving pixels.

FIG. 14A and FIG. 14B are diagrams each illustrating a structure example of a display panel.

FIG. 15 is a diagram illustrating a structure example of a display panel.

FIG. 16 is a diagram illustrating a structure example of a display panel.

FIG. 17 is a diagram illustrating a structure example of a display panel.

FIG. 18 is a diagram illustrating a structure example of a display panel.

FIG. 19 is a diagram illustrating a structure example of a display panel.

FIG. 20 is a diagram illustrating a structure example of a display panel.

FIG. 21A and FIG. 21B are diagrams each illustrating a vertical transistor.

FIG. 22A and FIG. 22B are diagrams each illustrating a vertical transistor.

### MODE FOR CARRYING OUT THE INVENTION

Embodiments will be described in detail with reference to the drawings. Note that the present invention is not limited to the following description, and it will be readily understood by those skilled in the art that modes and details of the present invention can be modified in various ways without departing from the spirit and scope of the present invention. Therefore, the present invention should not be construed as being limited to the description of embodiments below. Note that in structures of the invention described below, the same reference numerals are used in common, in different drawings, for the same portions or portions having similar functions, and a repeated description thereof is omitted in some cases. Note that the hatching of the same component that constitutes a drawing is sometimes omitted or changed as appropriate in different drawings.

In addition, even in the case where a single component is illustrated in a circuit diagram, the component may be composed of a plurality of parts as long as there is no functional inconvenience. For example, in some cases, a plurality of transistors that operate as a switch are connected in series or in parallel. Furthermore, in some cases, capacitors are separately arranged in a plurality of positions.

In addition, one conductor has a plurality of functions of a wiring, an electrode, a terminal, and the like in some cases. In this specification, a plurality of names are used for the same component in some cases. Even in the case where components are illustrated in a circuit diagram as if they were directly connected to each other, the components may actually be connected to each other through one or more conductors; in this specification, even such a structure is included in the category of direct connection.

### Embodiment 1

In this embodiment, electronic devices of one embodiment of the present invention will be described.

One embodiment of the present invention is a watch-type electronic device. The electronic device includes a display panel and an optical device which are placed in a region surrounded by a case and a bezel. A first component included in the optical device is fixed to the bezel, and rotating the bezel enables switching between a mode in which display on the display panel can be seen from a distance (hereinafter referred to as a distant mode) and a mode in which display on the display panel can be seen in proximity (hereinafter referred to as a proximate mode).

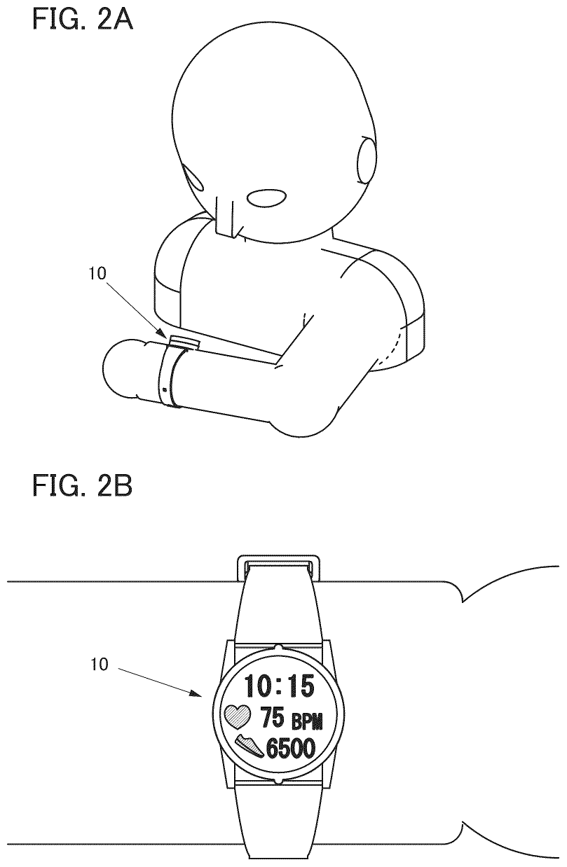

FIG. 2A is a diagram illustrating how an electronic device 10 is viewed in the distant mode. FIG. 2B is a diagram illustrating an example of display of the electronic device 10 in the distant mode. The distant mode is a mode in which the display is seen with a distance of several tens of centimeters from the eyes like when a watch is looked at; it is suitable when simple information such as time, healthcare information, or a notification sent from a smartphone is looked at.

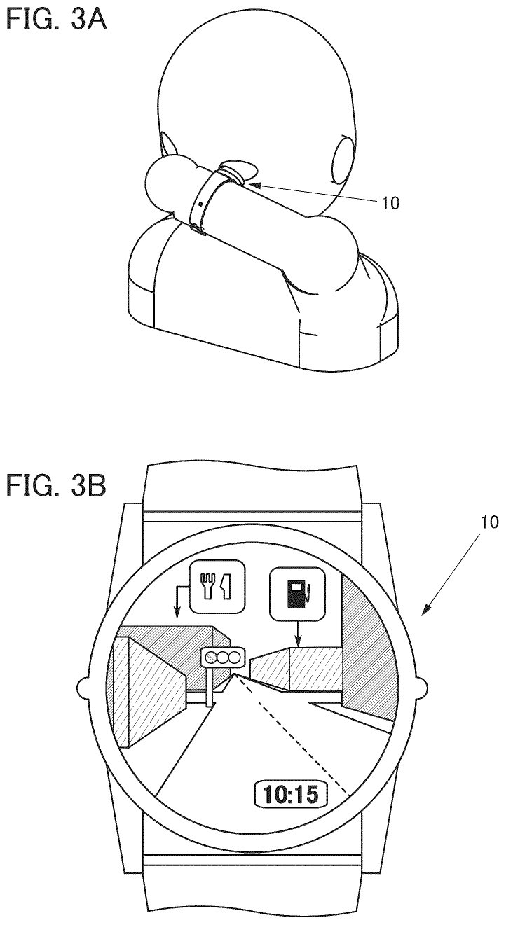

FIG. 3A is a diagram illustrating how the electronic device 10 is viewed in the proximate mode. FIG. 3B is a diagram illustrating an example of display of the electronic device 10 in the proximate mode. The proximate mode is a mode in which the distance between an eye and the optical device is made close for viewing the display, like VR goggles, and is suitably used in the case where the amount of information is large, such as an image and a long passage. In the proximate mode, visual information that is difficult to look at in the distant mode can be looked at with high visibility. Note that the proximate mode is viewing with a single eye, and either of the left or right eye can be used.

As described above, with the use of one embodiment of the present invention, the electronic device with a small size and high visibility, capable of switching the viewing modes, can be provided.

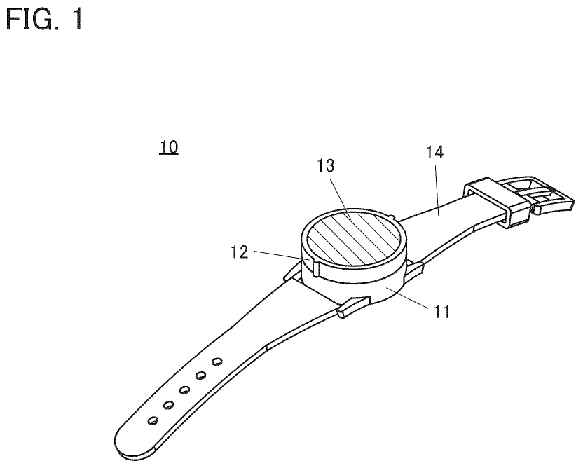

FIG. 1 is a diagram illustrating the electronic device 10. The electronic device 10 is a watch-type device, and includes a case 11, a bezel 12, a dial window 13, and a band 14. Here, the case refers to a container in which a display panel, an optical device, a battery, a variety of circuit components, and the like included in an electronic device are placed, and has a portion connected with the band. The bezel refers to a ring-like component provided over the top of the case. The dial window is a transparent part for protecting devices placed in the case and is fixed to the bezel or the case.

In one embodiment of the present invention, the bezel 12 is not fixed to the case 11, and can be rotated in the clockwise direction or the counterclockwise direction seen from above. Note that it can also be said that the bezel 12 is fixed to the case 11 with a rotation mechanism therebetween. Note that the rotation mechanism may be provided as an independent component or may be provided as part of the bezel 12 or the case 11.

The bezel 12 is fixed to one or more components included in the optical device. In other words, rotating the bezel 12 enables some components included in the optical device to be rotated and the operation of the optical device to be switched.

Note that although the case and the bezel are described as individual components here, it is also possible to call the entirety “case” or “housing” and to describe that the case or the housing has a structure in which its upper portion is rotatable. In addition, the rotation of the bezel or the like is not necessarily limited to manual rotation, but may be performed by electric power using a motor or the like. In that case, an instruction of rotation operation may be externally made (e.g., from a smartphone or a remote controller). Furthermore, a clockwork mechanism or the like may be provided to allow return from the rotation position to the initial position with a one-touch action.

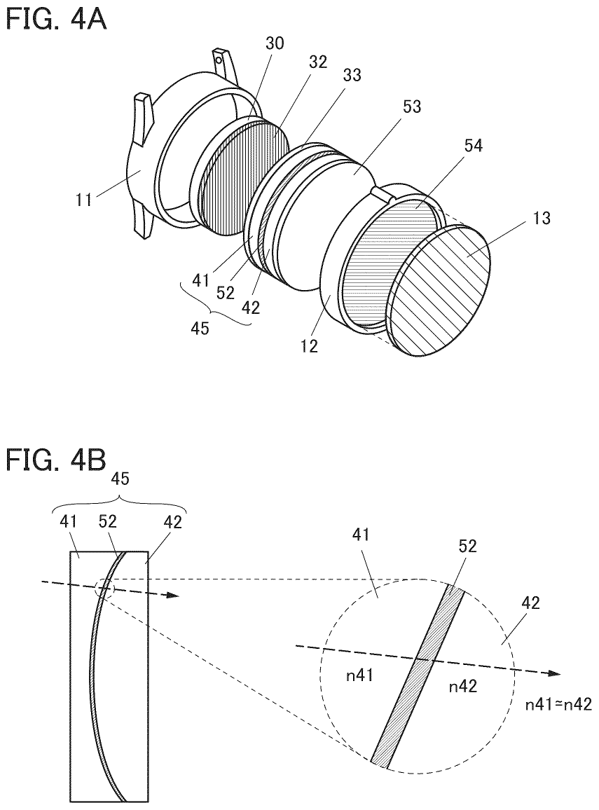

FIG. 4A is a diagram illustrating the display panel and the optical device that are placed in a region surrounded by the case 11 and the bezel 12. Note that components other than the display panel and the optical device (a battery, a circuit component, and the like) are not illustrated.

The display panel 30 and the optical device are placed such that light emitted from the display panel 30 is emitted to the bezel side (the dial window 13 side) through the optical device. The basic structure of the optical device is an optical system utilizing reflection, which can be used in a VR device or the like, and is sometimes referred to as a pancake lens because of its thin shape.

With this structure, display on the display panel 30 can be viewed in a state where the viewing angle is widened (in a state where the magnification is increased) by the optical device, which allows a large amount of information to be viewed (the proximate mode). Furthermore, when some components of the optical device are rotated, light emitted from the display panel 30 can be emitted substantially straight ahead without being reflected in the optical device. In other words, display on the display panel 30 can be viewed at the same magnification or a low magnification (distant mode).

A display surface of the display panel 30 intersects with the optical axis of the optical device perpendicularly and is placed to include a region overlapping with the optical device. Note that the term “perpendicular” indicates that the angle formed between two straight lines is greater than or equal to 85° and less than or equal to 95°. Here, one of the two straight lines refers to the optical axis of the optical device, and the other refers to a straight line parallel to the display surface (display portion).

The optical device has a structure in which a linear polarizing plate 32, a retardation plate 33, an optical unit 45, a retardation plate 53, and a reflective polarizing plate 54 are placed to overlap with each other in this sequence, and is provided in the case 11 and the bezel 12 such that the reflective polarizing plate 54 is on the bezel 12 side. Although FIG. 4A illustrates an example in which the linear polarizing plate 32 is provided close to the display panel 30, the linear polarizing plate 32 may be provided close to the retardation plate 33.

Note that the combination of the linear polarizing plate 32 and the retardation plate 33 is also referred to as a circular polarizing plate that converts unpolarized light to circularly polarized light. The combination of the retardation plate 53 and the reflective polarizing plate 54 can also be referred to as a circular polarizing plate, and can also be referred to as a reflective circular polarizing plate.

The reflective polarizing plate 54 can be fixed to the bezel 12. The dial window 13 is provided on the light emission side of the reflective polarizing plate 54. As the dial window 13, a glass substrate, a resin substrate, a ceramic substrate, or the like with a high visible-light-transmitting property can be used, for example. The dial window 13 may have a function of a convex lens. When the dial window 13 has a function of a convex lens, display can be magnified and viewed even in the distant mode.

Alternatively, a solar cell having a high visible-light-transmitting property may be used as the dial window 13. It is also possible to provide the solar cell on the front or rear side of the dial window 13. As the solar cell, one with a photoelectric conversion layer formed using a material such as an organic semiconductor, perovskite, dichalcogenide, amorphous silicon, or CIGS (Cu—In—Ga—Se) can be used. Although the material itself preferably has a light-transmitting property, the light-transmitting property may be improved by reducing the thickness of the material. The light-transmitting property may be improved by processing the material into a linear shape or an island shape. Electric power generated by the solar cell can charge a secondary battery, which enables the operation time of the electronic device to be extended.

The optical unit 45 has a structure in which a layer 52 having a half mirror function is sandwiched between an element 41 and an element 42. FIG. 4B is a cross-sectional view of the optical unit 45 and a portion of it being enlarged. The layer 52 has a curved surface with a concave on the retardation plate 53 side. The element 41 and the element 42 can be formed using a material having a high visible-light transmittance, such as glass or a resin. The element 41 and the element 42 can be formed using the same material or materials whose refractive indices are close to each other. The layer 52 can be formed using one or both of a metal and a dielectric.

Such a structure makes it possible to eliminate or reduce a refractive index difference between the optical paths before and after passing through the layer 52, and thus to allow light passing through the optical unit 45 to go substantially straight ahead. Alternatively, refraction of light passing through the optical unit 45 can be reduced.

When there is a refractive index difference between the optical paths before and after the half mirror, transmitted light other than normal incident light is refracted. In the case where light transmitted through the half mirror is polarized light, the polarization state might be distorted by refraction, and stray light is likely to be generated.

Note that stray light refers to light that deviates from the normal optical path. Since stray light overlaps with light that forms a normal image in the electronic device, stray light is a factor causing deterioration of the quality of display to be viewed. Note that stray light appears in an unintended position and thus is also referred to as a ghost.

In order to view display on the display panel 30 at the same magnification in the distant mode, it is preferable that light passing through the optical unit 45 go substantially straight. In order to view display on the display panel 30 at a low magnification in the distant mode, it is preferable that the refraction of light passing through the optical unit 45 be small.

Note that an optical adhesive may be provided between the element 41 and the layer 52 and between the element 42 and the layer 52. For the optical adhesive, a material having a refractive index equivalent to or close to those of the element 41 and the element 42 is preferably used. Alternatively, a material having a refractive index between the refractive index of the element 41 and the refractive index of the element 42 is preferably used.

Here, a case) is considered where the element 41 is not provided, the layer 52 operates only on attenuation of light intensity, and light enters the element 42 from the air (refractive index: nₐ=1. The refractive index n₄₂ of the element 42, if the element 42 is assumed to be glass or a resin, is approximately 1.4 to 2.0, which leads to a difference in refractive index greater than or equal to 0.4, so that the element 42 functions as a lens and light is refracted.

Thus, in order to make light entering the optical unit 45 go straight ahead or reduce refraction, a difference between the refractive index n₄₁ of the element 41 and the refractive index n₄₂ of the element 42 is set to less than or equal to 0.3, preferably less than or equal to 0.2, further preferably less than or equal to 0.1.

Furthermore, the optical unit 45 needs to operate to collect light in the proximate mode. Thus, the optical unit 45 is required to have positive power as a whole by combining elements such as a convex lens and a concave mirror.

In the structure illustrated in FIG. 4A and FIG. 4B, an example is illustrated in which the light incident plane and emission plane of the optical unit 45 are flat. When the refractive indices of the element 41 and the element 42 are comparable in this structure, the element 41 and the element 42 do not operate as lenses and thus can be regarded as being suitable for the distant mode. Note that the element 41 and the element 42 are not limited to the mode illustrated in FIG. 4A and FIG. 4B as long as the curvature of the reflective surface of the layer 52 is increased and the optical unit 45 as a whole has positive power. In addition, when the optical unit 45 operates as a lens, display can be magnified and viewed even in the distant mode.

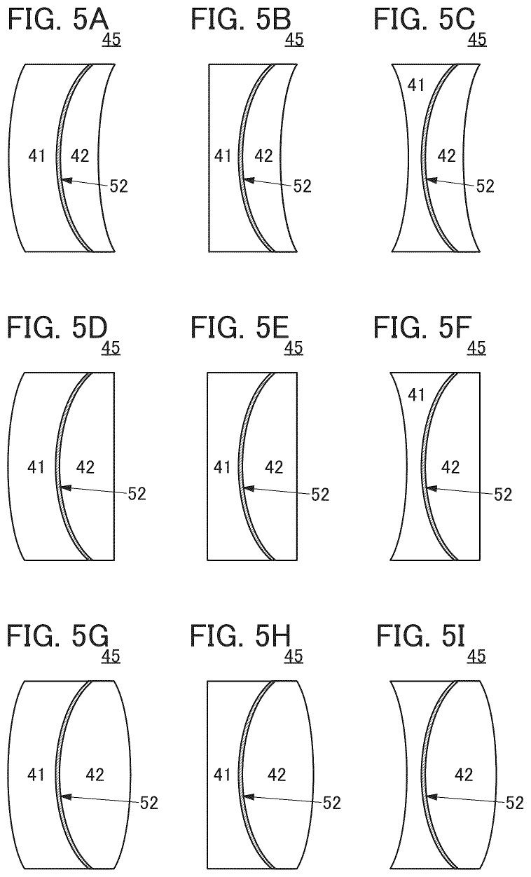

FIG. 5A to FIG. 5I illustrate typical modes of the element 41 and the element 42 that can be used for the optical unit 45. Note that the mode of the optical unit 45 illustrated as an example in FIG. 4A and FIG. 4B corresponds to FIG. 5E.

The modes of the element 41 and the element 42 illustrated in FIG. 5A to FIG. 5I are listed in Table 1. Note that, in Table 1, there is a case where the combination of the element 41 and the element 42 does not operate as a lens although the mode is indicated as a lens. Even in the case where the combination of the element 41 and the element 42 has negative power, low power, or no power, the optical unit 45 as a whole can have high positive power when the curvature of the layer 52 is increased. Note that a mode other than those in Table 1 may be employed as long as positive power can be obtained by increasing the curvature of the layer 52.

TABLE 1

| A | | B | | C | |
|---|---|---|---|---|---|
| Element 41 | Element 42 | Element 41 | Element 42 | Element 41 | Element 42 |
| Concave | Convex | Plane-concave | Convex | Biconcave lens | Convex |
| meniscus lens | meniscus lens | lens | meniscus lens | | meniscus lens |
| D | | E | | F | |
| Element 41 | Element 42 | Element 41 | Element 42 | Element 41 | Element 42 |
| Concave | Plane-convex | Plane-concave | Plane-convex | Biconcave lens | Plane-convex |
| meniscus lens | lens | lens | lens | | lens |
| G | | H | | I | |
| Element 41 | Element 42 | Element 41 | Element 42 | Element 41 | Element 42 |
| Concave | Biconvex lens | Plane-concave | Biconvex lens | Biconcave lens | Biconvex lens |
| meniscus lens | | lens | | | |

Each of the optical units 45 illustrated in FIG. 5A to FIG. 5I has the following features and can be selected as appropriate depending on the purpose.

As an indicator of image surface bending, there exists a Petzval sum that is calculated from the refractive indices and focal lengths of lenses (the element 41 and the element 42). A Petzval sum of 0 results in a flat image surface, which is a desirable characteristic for a lens system. To achieve this, it is necessary to make either the refractive index or the focal length negative; however, since the refractive index cannot be negative, it is preferable to use a concave lens with a negative focal length. Thus, to suppress image surface bending, it is preferable to use the optical unit 45 with one of the structures shown in FIG. 5A, FIG. 5B, FIG. 5C, FIG. 5F, and FIG. 5I.

Refraction is accompanied by chromatic aberration, and combining positive and negative powers can be effective for correcting chromatic aberration. Even if the incident plane is flat, chromatic aberration occurs unless the light is parallel. Thus, a combination of surfaces that can correct each other (a convex surface and a concave surface) is advantageous. Thus, to suppress chromatic aberration, it is preferable to use the optical unit 45 with one of the structures shown in FIG. 5A, FIG. 5B, FIG. 5F, and FIG. 5I.

Simply put, a larger positive power allows for a shorter focal length and makes the entire optical system smaller. In the optical unit 45, most of the positive power is borne by the half mirror (the reflective surface of the layer 52), but if there is a convex surface, it is possible to make the focal length even shorter. Thus, to increase the positive power as much as possible, it is preferable to use an optical unit 45 with one of the structures shown in FIG. 5A, FIG. 5D, FIG. 5G, FIG. 5H, and FIG. 5I.

In an optical system utilizing circularly polarized light as in one embodiment of the present invention, a retardation plate is needed. The retardation plate is in a film form, and it is advantageous if the bonding surface is flat, considering that the retardation plate is directly attached to the optical unit 45. Thus, in terms of easy fabrication, it can be said that the use of the optical unit 45 having any of the structures illustrated in FIG. 5D, FIG. 5E, FIG. 5F, and FIG. 5I is preferable.

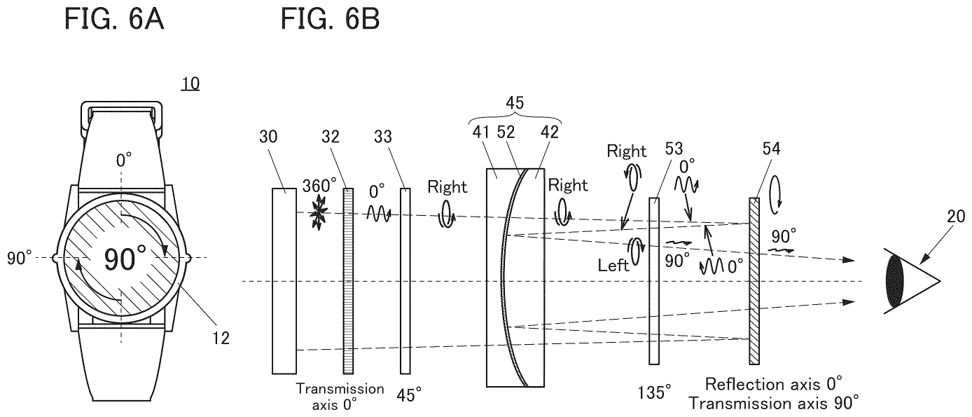

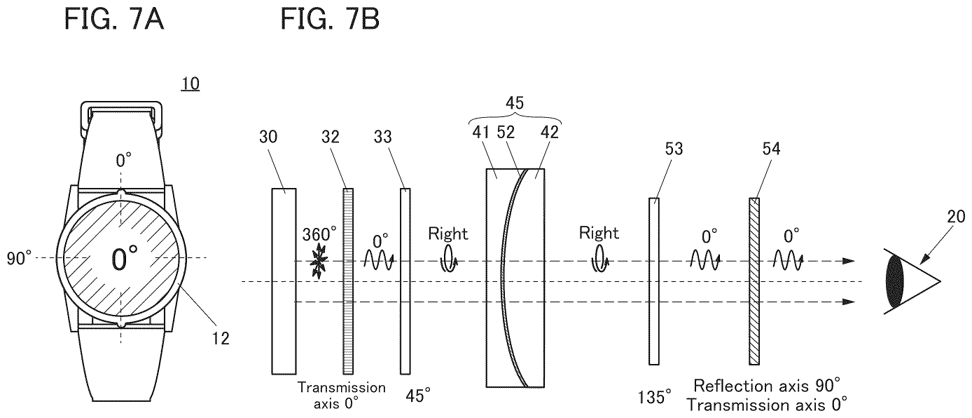

Next, the operation of the optical device of one embodiment of the present invention as a whole and the operation of each component are described with reference to FIG. 6A, FIG. 6B, FIG. 7A, and FIG. 7B. Note that although FIG. 4A illustrates an example in which some components are close to each other, the effect of one embodiment of the present invention can also be obtained by placing the components of the optical device apart from each other as illustrated in FIG. 6A, FIG. 6B, FIG. 7A, and FIG. 7B.

In the case where the above structure in which one component and another component are close to each other is employed, the components are preferably bonded to each other with the use of an optical adhesive which has high transmittance of the wavelength of light used (e.g., the wavelength range of visible light or the wavelength range from blue light to red light) and which does not cause birefringence and absorption of particular polarized light. Alternatively, the another component may be formed on and in contact with the one component not by attachment but by a coating method or the like. Alternatively, without using an adhesive or the like between the one component and the another component, the components may be placed in contact with each other. Alternatively, a space may be provided between the one component and the another component.

First, the operation of the optical device in the proximate mode is described with reference to FIG. 6A and FIG. 6B. Note that since the electronic device of one embodiment of the present invention is of a watch-type, a case is assumed where the electronic device is mainly used in a distant mode (normal time) and is used in the proximate mode when needed by switching the mode. However, the approximate mode is described first since the basic structure of the optical device is the proximate mode.

As mentioned above, rotating the bezel 12 seen from the top enables switching the viewing modes; here, a structure is employed in which the bezel 12 being at a reference position (0°) enables the distant mode and the bezel 12 being at a rotation angle of 90° enables switching to the proximate mode.

Note that in the case where the reflective polarizing plate 54 is fixed to the bezel 12, rotating the bezel by −90° (270°) also enables switching to the proximate mode. When the reference position is set to 0°, 180° can also be regarded as a reference position.

FIG. 6A is a diagram illustrating an electronic device 10 in the proximate mode where the bezel 12 is rotated from the reference position (0°) by 90°, and FIG. 6B is a cross-sectional view illustrating the operation of the optical device in the proximate mode. In FIG. 6B, part of an optical path is indicated by a dashed line.

Part of light emitted from the display panel 30 passes through the linear polarizing plate 32, the retardation plate 33, the optical unit 45 (the element 41, the layer 52 (half mirror), and the element 42), and the retardation plate 53, and is reflected by the reflective polarizing plate 54. Light reflected by the reflective polarizing plate 54 passes through the retardation plate 53 and the element 42, and is reflected again by the layer 52. Light reflected by the layer 52 passes through the element 42, the retardation plate 53, and the reflective polarizing plate 54, and is condensed to enter the eye 20.

By repeating reflection in the optical device in this manner, the optical path length can be secured; thus, an optical system with a short focal length can be achieved.

A liquid crystal panel including a liquid crystal element, an organic EL panel including an organic EL element, an LED panel including a micro LED, or the like can be used as the display panel 30. In particular, an organic EL panel is preferably used because a self-luminous and high-definition display portion is easily formed. In this specification and the like, alight-emitting diode whose chip area is less than or equal to 10000 μm² is referred to as a micro LED. Note that the LED panel is not limited to the micro LED; a light-emitting diode whose chip area is greater than 10000 μm² and less than or equal to 1 mm² (also referred to as a mini LED) may be used, for example.

The linear polarizing plate 32 can extract one linearly polarized light from light oscillating in 360° all directions. Note that although description is given in this embodiment on the assumption that the transmission axis of the linear polarizing plate 32 is 0°, 0° is not an absolute value but a reference value. That is, the polarization plane of the linearly polarized light extracted by the linear polarizing plate 32 is regarded as 0°. Accordingly, for example, 90° linearly polarized light in this embodiment refers to linearly polarized light obtained by rotating the polarization plane of the linearly polarized light extracted by the linear polarizing plate 32 by 90°.

The retardation plate 33 has a function of converting linearly polarized light into circularly polarized light. Here, a λ/4 plate (a quarter-wave plate) is used as the retardation plate 33. The λ/4 plate is overlaid with the linear polarizing plate 32 such that the angle of the slow axis of the λ/4 plate with respect to the axis of the linear polarized light emitted from the linear polarizing plate 32 becomes 45°, whereby dextrorotatory circularly polarized light (right circularly polarized light) is obtained. The λ/4 plate is overlaid with the linear polarizing plate 32 such that the angle of the slow axis of the λ/4 plate with respect to the axis of the linearly polarized light emitted from the linear polarizing plate 32 becomes 135° (45°), whereby levorotatory circularly polarized light (left circularly polarized light) is obtained. In one embodiment of the present invention, either right circularly polarized light or left circularly polarized light may be used as long as the combination with the characteristics of the reflective polarizing plate 54 described later is appropriate. Here, the slow axis of the retardation plate 33 is set to 45° with respect to the axis of the linearly polarized light (0°).

For the optical unit 45, the above description can be referred to. The layer 52 functions as a concave mirror having positive power, so that display on the display panel 30 can be enlarged.

The retardation plate 53 has a function of reversibly converting linearly polarized light and circularly polarized light. The λ/4 plate (a quarter-wave plate) can be used as the retardation plate 53 as well as the retardation plate 33. When the slow axis of the retardation plate 33 is placed at 45°, the retardation plate 53 is placed at 135°.

The reflective polarizing plate 54 can transmit linearly polarized light whose oscillating direction coincides with the transmission axis, and can reflect linearly polarized light that is orthogonal to the transmission axis. A wire grid polarizing plate or a dielectric multilayer film, for example, can be used as the reflective polarizing plate. Here, the reflective polarizing plate is placed such that the reflection axis is at 0° and the transmission axis is at 90°.

Note that as another component, a lens that has a function of enlarging display on the display panel 30 may be provided. A lens having positive power can be used as the lens. The number of lenses is not limited to one, and a plurality of lenses may be combined. For example, the lens can be formed by combining lenses selected from a biconvex lens, a plano-convex lens, a biconcave lens, a plano-concave lens, a convex meniscus lens, and a concave meniscus lens. Furthermore, the lens is not limited to a spherical lens and may be an aspherical lens.

Details of the polarization state in the optical device described above are described with reference to the optical path illustrated in FIG. 6B.

Light oscillating in 360° all directions that is emitted from the display panel 30 is incident on the linear polarizing plate 32. The transmission axis of the linear polarizing plate 32 is 0°, and 0° linearly polarized light is emitted from the linear polarizing plate 32.

The 0° linearly polarized light emitted from the linear polarizing plate 32 is converted into right circularly polarized light by the retardation plate 33. The right circularly polarized light emitted from the retardation plate 33 passes through the optical unit 45 and enters the retardation plate 53, and is converted into 0° linearly polarized light. The 0° linearly polarized light emitted from the retardation plate 53 is reflected by the reflective polarizing plate 54 whose reflection axis is 0°, and the light enters the retardation plate 53 and is converted into right circularly polarized light.

The right circularly polarized light emitted from the retardation plate 53 passes through the element 42 and is reflected by the layer 52, whereby being inverted to the left circularly polarized light with an opposite rotational direction. The left circularly polarized light inverted by the layer 52 passes through the element 42, and the light enters the retardation plate 53 and is converted into 90° linearly polarized light. The 90° linearly polarized light emitted from the retardation plate 53 passes through the reflective polarizing plate 54 whose transmission axis is 90° and enters an eye 20.

With the use of linearly polarized light, circularly polarized light, the half mirror (layer 52), and the reflective polarizing plate in this manner, reflection and transmission can be selectively performed. Thus, the optical path length can be secured in a limited space, and the focal length of the optical device can be shortened.

Note that although an example in which right circularly polarized light is used as light entering the optical unit 45 is described above, left circularly polarized light may be used.

The above is the description of the operation of the optical device in the proximate mode.

Next, the operation of the optical device in the distant mode is described. FIG. 7A is a diagram illustrating the electronic device 10 in the distant mode where the bezel 12 is at the reference position (0°), and FIG. 7B is a cross-sectional view illustrating the operation of the optical device in the distant mode. In FIG. 7B, part of an optical path is indicated by a dashed line.

Components of the optical device are the same as those in the proximate mode. However, since the position of the bezel 12 is at the reference position (0°), the reflective polarizing plate 54 fixed to the bezel 12 is placed such that the reflection axis is at 90° and the transmission axis is at 0°.

In the proximate mode, 0° linearly polarized light converted from right circularly polarized light by the retardation plate 53 is reflected by the reflective polarizing plate 54 placed such that the reflection axis is at 0° and the transmission axis is at 90°. Meanwhile, since in the distant mode, the reflective polarizing plate 54 is placed such that the reflection axis is at 90° and the transmission axis is at 0°; 0° linearly polarized light passes through the reflective polarizing plate 54 without being reflected by the reflective polarizing plate 54.

That is, since light does not return to the layer 52, the light does not receive positive power (operation of the concave mirror) due to reflection; hence, in the case where the optical device does not have another element that functions as a lens, the display of the display panel 30 can be seen at the same magnification or a magnification close to the same magnification without enlargement.

The above is the description of the operation of the optical device in the distant mode. Note that the structures of the display panel 30 and the optical device illustrated in FIG. 6A, FIG. 6B, FIG. 7A, and FIG. 7B are examples, and other structures can also be used.

Note that although the structure in which the viewing mode is switched by rotating the reflective polarizing plate 54 is described above, the viewing mode can be switched by rotating a different component.

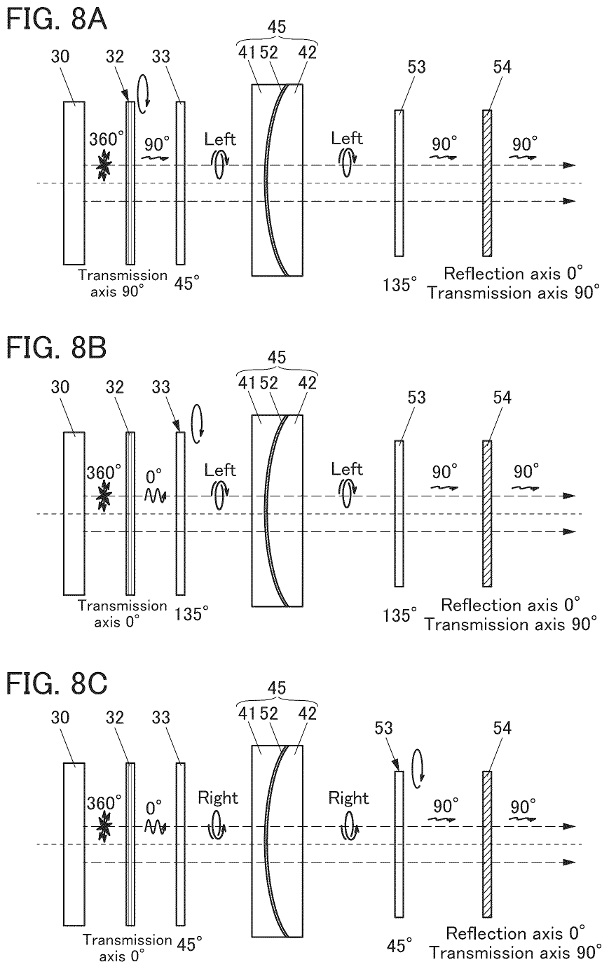

For example, as illustrated in FIG. 8A, a state where the linear polarizing plate 32 is placed such that the transmission axis is at 90° may enable the distant mode, whereas a state where the linear polarizing plate 32 is rotated by 90° (see FIG. 6B) may enable the proximate mode.

In the mode of FIG. 8A, the 90° linearly polarized light emitted from the linear polarizing plate 32 is converted into left circularly polarized light by the retardation plate 33. The left circularly polarized light emitted from the retardation plate 33 passes through the optical unit 45 and enters the retardation plate 53, and is converted into 90° linearly polarized light. The 90° linearly polarized light emitted from the retardation plate 53 passes through the reflective polarizing plate 54 whose transmission axis is at 90°, and enters the eye. Thus, placing the linear polarizing plate 32 such that the transmission axis is at 90° can achieve the distant mode.

Alternatively, as illustrated in FIG. 8B, a state where the retardation plate 33 is placed such that the retardation plate 33 is at 135° may be the distant mode, and a state where the retardation plate 33 is rotated by 90° (see FIG. 6B) may be the proximate mode.

In the mode of FIG. 8B, the 0° linearly polarized light emitted from the linear polarizing plate 32 is converted into left circularly polarized light by the retardation plate 33. The left circularly polarized light emitted from the retardation plate 33 passes through the optical unit 45 and enters the retardation plate 53, and is converted into 90° linearly polarized light. The 90° linearly polarized light emitted from the retardation plate 53 passes through the reflective polarizing plate 54 whose transmission axis is at 90°, and enters the eye. Thus, placing the retardation plate 33 such that the slow axis is at 135° can achieve the distant mode.

Alternatively, as illustrated in FIG. 8C, a state where the retardation plate 53 is placed such that the slow axis is at 45° may be the distant mode, and a state where the retardation plate 53 is rotated by 90° (see FIG. 6B) may be the proximate mode.

In the mode of FIG. 8C, the 0° linearly polarized light emitted from the linear polarizing plate 32 is converted into right circularly polarized light by the retardation plate 33. The right circularly polarized light emitted from the retardation plate 33 passes through the optical unit 45 and enters the retardation plate 53, and is converted into 90° linearly polarized light. The 90° linearly polarized light emitted from the retardation plate 53 passes through the reflective polarizing plate 54 whose transmission axis is at 90°, and enters the eye. Thus, placing the retardation plate 53 such that the slow axis is at 45° can achieve the distant mode.

Note that in the case where the retardation plate 33 or the retardation plate 53 is attached to the optical unit 45 in the structures illustrated in FIG. 8B and FIG. 8C, the optical unit 45 may also be rotated together.

Since the structures of FIG. 8A to FIG. 8C entail complex coordination with the rotation of the bezel 12, it is preferable to provide a rotatable component at a place different from that of the bezel 12. For example, it is preferable to provide the rotatable component between the case 11 and the bezel 12 or in a region of the case, and to fix the component to one of the components of the optical device (the linear polarizing plate 32, the retardation plate 33, or the retardation plate 53).

In the case where the rotation of the bezel 12 is coordinated with the viewing mode, it is preferable that a component placed at the edge of the optical device, which is close to the bezel 12, is, be fixed to the bezel 12. Thus, in the case where the rotation of the bezel 12 is coordinated with the viewing mode, a structure in which the viewing mode is switched by rotation of the reflective polarizing plate 54 illustrated in FIG. 6A, FIG. 6B, FIG. 7A, and FIG. 7B is most preferable.

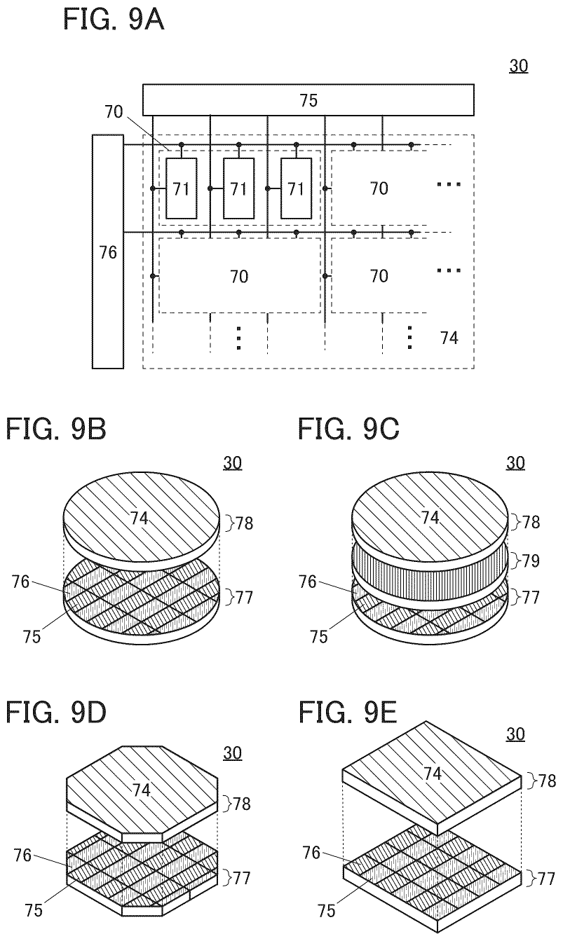

FIG. 9A is a diagram illustrating the display panel 30 included in the electronic device of one embodiment of the present invention. The display panel 30 includes a pixel array 74, a circuit 75, and a circuit 76. The pixel array 74 includes pixels 70 arranged in a column direction and a row direction.

The pixel 70 can include a plurality of subpixels 71. The subpixel 71 has a function of emitting light for display.

Note that in this specification, although the minimum unit in which an independent operation is performed in one “pixel” is defined as a “subpixel” in the description for convenience, a “pixel” may be replaced with a “region” and a “subpixel” may be replaced with a “pixel.”

The subpixel 71 includes a light-emitting device that emits visible light. An EL element such as an OLED (Organic Light Emitting Diode) or a QLED (Quantum-dot Light Emitting Diode) is preferably used as the light-emitting device. As a light-emitting substance contained in the EL element, a substance that emits fluorescent light (a fluorescent material), a substance that emits phosphorescent light (a phosphorescent material), a substance that exhibits thermally activated delayed fluorescence (a thermally activated delayed fluorescent (TADF) material), an inorganic compound (a quantum dot material or the like), and the like can be given. In addition, an LED (Light Emitting Diode) such as a micro LED can be also used as the light-emitting device.

The circuit 75 and the circuit 76 are driver circuits for driving the subpixel 71. The circuit 75 can have a function of a source driver circuit, and the circuit 76 can have a function of a gate driver circuit. A shift register circuit or the like can be used as each of the circuit 75 and the circuit 76, for example.

Note that as illustrated in FIG. 9B, the display panel 30 may have a structure where the circuit 75 and the circuit 76 are provided in a layer 77, the pixel array 74 is provided in a layer 78, and the layer 77 and the layer 78 overlap with each other. This structure enables the formation of a display device with a narrow bezel.

In addition, when the driver circuits are provided below the pixel array 74, wiring length can be shortened and wiring capacitance can be reduced. Accordingly, a display panel capable of a high-speed operation with low power consumption can be provided.

In addition, when each of the circuit 75 and the circuit 76 is divided and arranged as illustrated in FIG. 9B, part of the pixel array 74 can be driven. For example, part of image data in the pixel array 74 can be rewritten. Furthermore, part of the pixel array 74 can be operated at different operating frequency.

The layout and area of the circuit 75 and the circuit 76 illustrated in FIG. 9B are examples and can be changed as appropriate. In addition, parts of the circuit 75 and the circuit 76 can be formed in the same layer as the pixel array 74. Furthermore, a circuit such as a memory circuit, an arithmetic circuit, or a communication circuit may be provided in the layer 77.

In this structure, for example, the layer 77 can be provided on a single crystal silicon substrate, the circuit 75 and the circuit 76 can be formed with transistors including silicon in channel formation regions (hereinafter Si transistors), and pixel circuits included in the pixel array 74 provided in the layer 78 can be formed with transistors including a metal oxide in channel formation regions (hereinafter OS transistors). An OS transistor can be formed with a thin film and can be formed to be stacked over a Si transistor.

Note that as illustrated in FIG. 9C, a structure where a layer 79 including OS transistors is provided between the layer 77 and the layer 78 may be employed. Some of the pixel circuits included in the pixel array 74 in the layer 79 can be provided with OS transistors. Alternatively, some of the circuit 75 and the circuit 76 can be provided with OS transistors. Alternatively, some of the circuits that can be provided in the layer 77, such as a memory circuit, an arithmetic circuit, and a communication circuit, can be provided with OS transistors.

Although FIG. 9B illustrates an example in which the top view of the display panel 30 is circular, the display panel 30 may have a polygonal shape. The top view may be octagonal, for example, as illustrated in FIG. 9D. Alternatively, the top view may be quadrangular as illustrated in FIG. 9E.

At least part of this embodiment can be implemented in combination with the other embodiments and examples described in this specification as appropriate.

### Embodiment 2

In this embodiment, structure examples of a display panel that can be employed for the electronic device according to one embodiment of the present invention will be described. A display panel described below as an example can be employed for the display panel 30 in Embodiment 1.

One embodiment of the present invention is a display panel including light-emitting elements (also referred to as light-emitting devices). The display panel includes two or more pixels of different emission colors. The pixels include light-emitting elements. The light-emitting elements each include a pair of electrodes and an EL layer therebetween. The light-emitting elements are preferably organic EL elements (organic electroluminescent elements). Two or more light-emitting elements of different emission colors include EL layers containing different light-emitting materials. For example, when three kinds of light-emitting elements that emit red (R), green (G), and blue (B) light are included, a full-color display panel can be achieved.

In the case of manufacturing a display panel including a plurality of light-emitting elements of different emission colors, at least layers (light-emitting layers) containing light-emitting materials each need to be formed in an island shape. In the case of separately forming part or the whole of an EL layer, a method for forming an island-shaped organic film by an evaporation method using a shadow mask such as a metal mask is known. However, this method causes a deviation from the designed shape and position of the island-shaped organic film due to various influences such as the accuracy of the metal mask, the positional deviation between the metal mask and a substrate, a warp of the metal mask, and expansion of the outline of a deposited film due to vapor scattering, for example; accordingly, it is difficult to achieve the high definition and high aperture ratio of the display panel. In addition, the outline of the layer might blur during evaporation, so that the thickness of an end portion might be reduced. That is, the thickness of an island-shaped light-emitting layer might vary from place to place. In addition, in the case of manufacturing a display panel with a large size, high resolution, or high definition, a manufacturing yield might be reduced because of low dimensional accuracy of the metal mask and deformation due to heat or the like. Thus, a measure has been taken for a pseudo increase in definition (also referred to as pixel density) by employing a unique pixel arrangement such as a PenTile arrangement.

Note that in this specification and the like, the term “island shape” refers to a state where two or more layers formed using the same material in the same step are physically separated from each other. For example, the term “island-shaped light-emitting layer” refers to a state where the light-emitting layer and its adjacent light-emitting layer are physically separated from each other.

In one embodiment of the present invention, fine patterning of EL layers is performed by using a photolithography method without using a shadow mask such as a fine metal mask (an FMM). Accordingly, it is possible to achieve a display panel with high definition and a high aperture ratio, which has been difficult to achieve. Moreover, since the EL layers can be formed separately, it is possible to achieve a display panel that performs extremely clear display with high contrast and high display quality. Note that, fine patterning of the EL layers may be performed using both a metal mask and a photolithography method, for example.

In addition, part or the whole of the EL layer can be physically divided from each other. This can inhibit leakage current flowing between adjacent light-emitting elements through a layer (also referred to as a common layer) shared by the light-emitting elements. Thus, it is possible to prevent unintended light emission due to crosstalk, so that a display panel with extremely high contrast can be achieved. In particular, a display panel having high current efficiency at low luminance can be achieved.

In one embodiment of the present invention, the display panel can be also obtained by combining a light-emitting element that emits white light with a color filter. In that case, light-emitting elements having the same structure can be employed as light-emitting elements provided in pixels (subpixels) that emit light of different colors, which allows all the layers to be common layers. In addition, part or the whole of the EL layer may be divided from each other in a step using a photolithography method. Thus, leakage current through the common layer is inhibited; accordingly, a high-contrast display panel can be achieved. In particular, when an element has a tandem structure where a plurality of light-emitting layers are stacked with a highly conductive intermediate layer therebetween, leakage current through the intermediate layer can be effectively prevented, so that a display panel with high luminance, high definition, and high contrast can be achieved.

In the case where the EL layer is processed by a photolithography method, part of the light-emitting layer is sometimes exposed to cause degradation. Thus, an insulating layer covering at least a side surface of the island-shaped light-emitting layer is preferably provided. The insulating layer may cover part of a top surface of an island-shaped EL layer. For the insulating layer, a material having a barrier property against water and oxygen is preferably used. For example, an inorganic insulating film that is less likely to diffuse water or oxygen can be used. This can inhibit degradation of the EL layer and can achieve a highly reliable display panel.

Moreover, between two adjacent light-emitting elements, there is a region (a concave portion) where none of the EL layers of the light-emitting elements is provided. In the case where a common electrode or a common electrode and a common layer are formed to cover the concave portion, a phenomenon where the common electrode is divided by a step at an end portion of the EL layer (such a phenomenon is also referred to as disconnection) might occur, which might cause insulation of the common electrode over the EL layer. In view of this, a local gap between the two adjacent light-emitting elements is preferably filled with a resin layer (also referred to as local filling planarization, or LFP) functioning as a planarization film. The resin layer has a function of a planarization film. This structure can inhibit disconnection of the common layer or the common electrode and can achieve a highly reliable display panel.

More specific structure examples of the display panel according to one embodiment of the present invention will be described below with reference to drawings.

### Structure Example 1

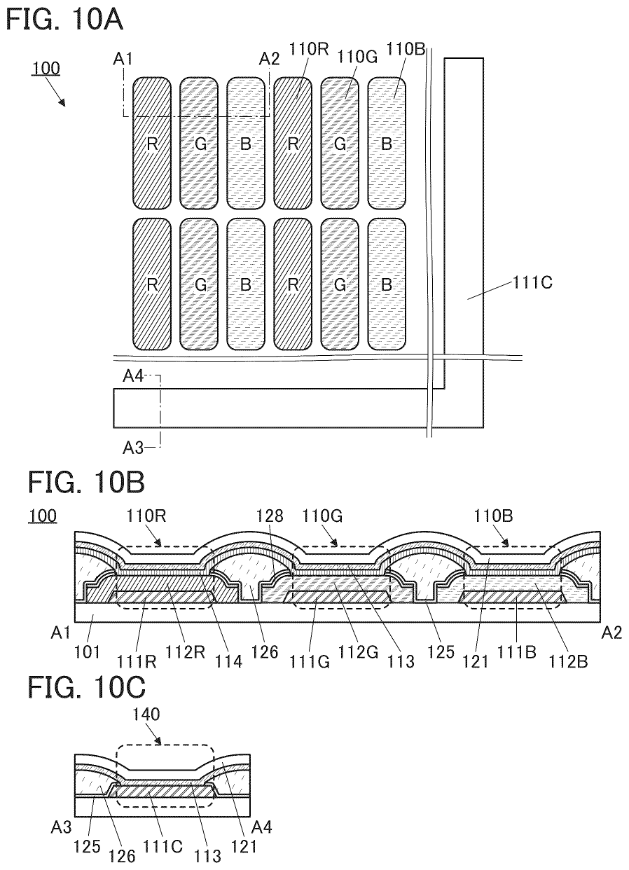

FIG. 10A illustrates a schematic top view of a display panel 100 according to one embodiment of the present invention. The display panel 100 includes, over a substrate 101, a plurality of light-emitting elements 110R exhibiting red, a plurality of light-emitting elements 110G exhibiting green, and a plurality of light-emitting elements 110B exhibiting blue. In FIG. 10A, light-emitting regions of the light-emitting elements are denoted by R, G, and B to easily differentiate the light-emitting elements.

The light-emitting elements 110R, the light-emitting elements 110G, and the light-emitting elements 110B are each arranged in a matrix. FIG. 10A illustrates what is called a stripe arrangement, in which the light-emitting elements of the same color are arranged in one direction. Note that an arrangement method of the light-emitting elements is not limited thereto; an arrangement method such as an S-stripe arrangement, a delta arrangement, a Bayer arrangement, or a zigzag arrangement may be employed, or a PenTile arrangement, a diamond arrangement, or the like can be also used.

As each of the light-emitting elements 110R, the light-emitting elements 110G, and the light-emitting elements 110B, an OLED (Organic Light Emitting Diode), or a QLED (Quantum-dot Light Emitting Diode) is preferably used, for example. As the light-emitting substance contained in the EL element, not only an organic compound but also an inorganic compound (a quantum dot material or the like) can be used.

FIG. 10A also illustrates a connection electrode 111C that is electrically connected to a common electrode 113. The connection electrode 111C is supplied with a potential (e.g., an anode potential or a cathode potential) that is to be supplied to the common electrode 113. The connection electrode 111C is provided outside a display region where the light-emitting elements 110R and the like are arranged.

The connection electrode 111C can be provided along the outer periphery of the display region. For example, the connection electrode 111C may be provided along one side of the outer periphery of the display region, or the connection electrode 111C may be provided across two or more sides of the outer periphery of the display region. That is, in the case where the display region has a rectangular top surface shape, the top surface shape of the connection electrode 111C can be a band shape (a rectangle), an L shape, a U shape (a square bracket shape), a quadrangular shape, or the like. Note that in this specification and the like, a top surface shape refers to a shape in a plan view, i.e., a shape seen from above.

FIG. 10B and FIG. 10C are schematic cross-sectional views corresponding to the dashed-dotted line A1-A2 and the dashed-dotted line A3-A4 in FIG. 10A. FIG. 10B illustrates a schematic cross-sectional view of the light-emitting element 110R, the light-emitting element 110G, and the light-emitting element 110B, and FIG. 10C illustrates a schematic cross-sectional view of a connection portion 140 where the connection electrode 111C and the common electrode 113 are connected to each other.

The light-emitting element 110R includes a pixel electrode 111R, an organic layer 112R, a common layer 114, and the common electrode 113. The light-emitting element 110G includes a pixel electrode 111G, an organic layer 112G, the common layer 114, and the common electrode 113. The light-emitting element 110B includes a pixel electrode 111B, an organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R included in the light-emitting element 110R contains at least a light-emitting organic compound that emits red light. The organic layer 112G included in the light-emitting element 110G contains at least a light-emitting organic compound that emits green light. The organic layer 112B included in the light-emitting element 110B contains at least a light-emitting organic compound that emits blue light. Each of the organic layer 112R, the organic layer 112G, and the organic layer 112B can be also referred to as an EL layer and includes at least a layer containing a light-emitting substance (a light-emitting layer).

Hereinafter, the term “light-emitting element 110” is sometimes used to describe matters common to the light-emitting element 110R, the light-emitting element 110G, and the light-emitting element 1101B. Similarly, in the description of matters common to components that are distinguished from each other using alphabets, such as the organic layer 112R, the organic layer 112G, and the organic layer 112B, reference numerals without alphabets are sometimes used.

The organic layer 112 and the common layer 114 can each independently include one or more of an electron-injection layer, an electron-transport layer, a hole-injection layer, and a hole-transport layer. For example, it is possible to employ a structure where the organic layer 112 includes a stacked-layer structure of a hole-injection layer, a hole-transport layer, a light-emitting layer, and an electron-transport layer from the pixel electrode 111 side and the common layer 114 includes an electron-injection layer.

The pixel electrode 111R, the pixel electrode 111G, and the pixel electrode 111B are provided for the respective light-emitting elements. In addition, the common electrode 113 and the common layer 114 are each provided as a continuous layer shared by the light-emitting elements. A conductive film having a property of transmitting visible light is used for either the pixel electrodes or the common electrode 113, and a conductive film having a reflective property is used for the other. When the pixel electrodes have light-transmitting properties and the common electrode 113 has a reflective property, a bottom-emission display panel can be obtained. In contrast, when the pixel electrodes have reflective properties and the common electrode 113 has a light-transmitting property, a top-emission display panel can be obtained. Note that when both the pixel electrodes and the common electrode 113 have light-transmitting properties, a dual-emission display panel can be also obtained.

A protective layer 121 is provided over the common electrode 113 to cover the light-emitting element 110R, the light-emitting element 110G, and the light-emitting element 1101B. The protective layer 121 has a function of preventing diffusion of impurities such as water into each light-emitting element from the above.

An end portion of the pixel electrode 111 preferably has a tapered shape. In the case where the end portion of the pixel electrode 111 has a tapered shape, the organic layer 112 that is provided along the end portion of the pixel electrode 111 can also have a tapered shape. When the end portion of the pixel electrode 111 has a tapered shape, coverage with the organic layer 112 provided beyond the end portion of the pixel electrode 111 can be increased. Furthermore, when the side surface of the pixel electrode 111 has a tapered shape, a material (for example, also referred to as dust or particles) in a manufacturing step is easily removed by processing such as cleaning, which is preferable.

Note that in this specification and the like, a tapered shape indicates a shape in which at least part of a side surface of a structure is inclined to a substrate surface. For example, a tapered shape preferably includes a region where an angle formed between the inclined side surface and the substrate surface (such an angle is also referred to as a taper angle) is less than 90°.

The organic layer 112 is processed into an island shape by a photolithography method. Thus, an angle formed between a top surface and a side surface of an end portion of the organic layer 112 is approximately 90°. In contrast, an organic film formed using an FMM (Fine Metal Mask) or the like has a thickness that tends to gradually decrease with decreasing the distance from an end portion, and has a top surface forming a slope in an area extending in the range of greater than or equal to 1 μm and less than or equal to 10 μm from the end portion, for example. Thus, such an organic film has a shape whose top surface and side surface are difficult to distinguish from each other.

An insulating layer 125, a resin layer 126, and a layer 128 are included between two adjacent light-emitting elements.

Between two adjacent light-emitting elements, side surfaces of the organic layers 112 are provided to face each other with the resin layer 126 therebetween. The resin layer 126 is positioned between the two adjacent light-emitting elements and is provided to fill end portions of the organic layers 112 and a region between the two organic layers 112. The resin layer 126 has a top surface with a smooth convex shape. The common layer 114 and the common electrode 113 are provided to cover the top surface of the resin layer 126.

The resin layer 126 functions as a planarization film that fills a step positioned between two adjacent light-emitting elements. Providing the resin layer 126 can prevent a phenomenon in which the common electrode 113 is divided by a step at an end portion of the organic layer 112 (such a phenomenon is also referred to as disconnection) from occurring and the common electrode over the organic layer 112 from being insulated.

An insulating layer containing an organic material can be suitably used as the resin layer 126. For the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of these resins, or the like can be used, for example. For the resin layer 126, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Alternatively, a photosensitive resin can be used for the resin layer 126. A photoresist may be used for the photosensitive resin. As the photosensitive resin, a positive photosensitive material or a negative photosensitive material can be used.

The resin layer 126 may contain a material absorbing visible light. For example, the resin layer 126 itself may be made of a material absorbing visible light, or the resin layer 126 may contain a pigment absorbing visible light. For example, for the resin layer 126, it is possible to use a resin that can be used as a color filter transmitting red, blue, or green light and absorbing other light, a resin that contains carbon black as a pigment and functions as a black matrix, or the like.

The insulating layer 125 is provided in contact with the side surfaces of the organic layers 112. In addition, the insulating layer 125 is provided to cover an upper end portion of the organic layer 112. Furthermore, part of the insulating layer 125 is provided in contact with atop surface of the substrate 101.

The insulating layer 125 is positioned between the resin layer 126 and the organic layer 112 and functions as a protective film for preventing contact between the resin layer 126 and the organic layer 112. When the organic layer 112 and the resin layer 126 are in contact with each other, the organic layer 112 might be dissolved by an organic solvent or the like used at the time of forming the resin layer 126. Therefore, the insulating layer 125 is provided between the organic layer 112 and the resin layer 126 to protect the side surfaces of the organic layer 112.

An insulating layer containing an inorganic material can be used for the insulating layer 125. For the insulating layer 125, an inorganic insulating film such as an oxide insulating film, a nitride insulating film, an oxynitride insulating film, or a nitride oxide insulating film can be used, for example. The insulating layer 125 may have either a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an ALD (Atomic Layer Deposition) method is employed for the insulating layer 125, it is possible to form the insulating layer 125 that has a small number of pinholes and has an excellent function of protecting the EL layer.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

For the formation of the insulating layer 125, a sputtering method, a CVD method, a PLD method, an ALD method, or the like can be used. The insulating layer 125 is preferably formed by an ALD method that provides good coverage.

In addition, a structure may be employed in which a reflective film (e.g., a metal film containing one or more selected from silver, palladium, copper, titanium, aluminum, and the like) is provided between the insulating layer 125 and the resin layer 126 so that light emitted from the light-emitting layer is reflected by the reflective film. This can improve light extraction efficiency.

The layer 128 is a remaining part of a protective layer (also referred to as a mask layer or a sacrificial layer) for protecting the organic layer 112 during etching of the organic layer 112. For the layer 128, a material that can be used for the insulating layer 125 can be used. It is particularly preferable to use the same material for the layer 128 and the insulating layer 125 because an apparatus or the like for processing can be used in common.

In particular, since a metal oxide film such as an aluminum oxide film or a hafnium oxide film or an inorganic insulating film such as a silicon oxide film that is formed by an ALD method has a small number of pinholes, such a film has an excellent function of protecting the EL layer and can be suitably used for the insulating layer 125 and the layer 128.

The protective layer 121 can have, for example, a single-layer structure or a stacked-layer structure including at least an inorganic insulating film. Examples of the inorganic insulating film include an oxide film and a nitride film, such as a silicon oxide film, a silicon oxynitride film, a silicon nitride oxide film, a silicon nitride film, an aluminum oxide film, an aluminum oxynitride film, and a hafnium oxide film. Alternatively, a semiconductor material or a conductive material such as indium gallium oxide, indium zinc oxide, indium tin oxide, or indium gallium zinc oxide may be used for the protective layer 121.

For the protective layer 121, a stacked film of an inorganic insulating film and an organic insulating film can be used. For example, a structure where an organic insulating film is sandwiched between a pair of inorganic insulating films is preferable. Furthermore, the organic insulating film preferably functions as a planarization film. This enables a top surface of the organic insulating film to be flat, which results in improved coverage with the inorganic insulating film thereover and a higher barrier property. Moreover, the top surface of the protective layer 121 is flat; therefore, when a structural object (e.g., a color filter, an electrode of a touch sensor, a lens array, or the like) is provided above the protective layer 121, the structural object can be less affected by an uneven shape caused by a lower structure, which is preferable.

FIG. 10C illustrates the connection portion 140 in which the connection electrode 111C and the common electrode 113 are electrically connected to each other. In the connection portion 140, an opening portion is provided in the insulating layer 125 and the resin layer 126 over the connection electrode 111C. The connection electrode 111C and the common electrode 113 are electrically connected to each other in the opening portion.

Note that although FIG. 10C illustrates the connection portion 140 in which the connection electrode 111C and the common electrode 113 are electrically connected to each other, the common electrode 113 may be provided over the connection electrode 111C with the common layer 114 therebetween. Particularly in the case where a carrier-injection layer is used as the common layer 114, for example, a material used for the common layer 114 has sufficiently low electrical resistivity and the common layer 114 can be formed to be thin. Thus, problems do not arise in many cases even when the common layer 114 is positioned in the connection portion 140. Accordingly, the common electrode 113 and the common layer 114 can be formed using the same shielding mask, so that manufacturing cost can be reduced.

### Structure Example 2

A display panel whose structure is partly different from that of Structure Example 1 is described below. Note that the above description can be referred to for portions common to those in Structure Example 1, and the description is omitted in some cases.

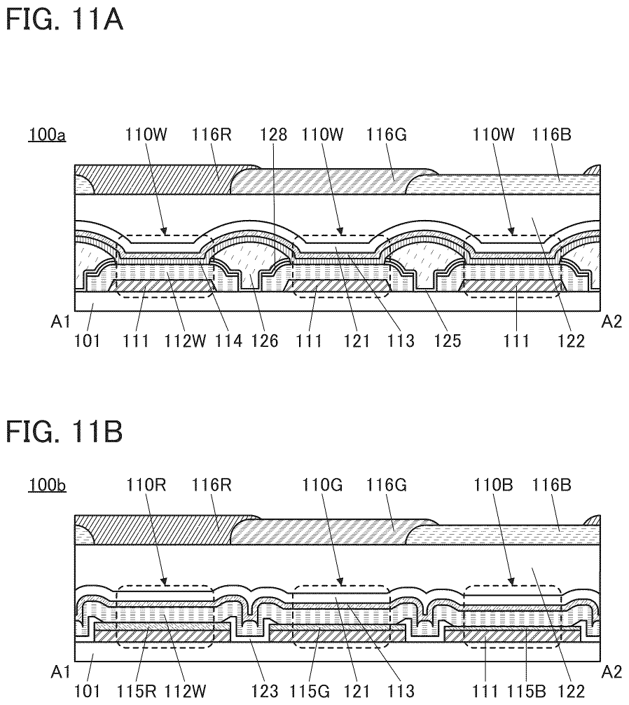

FIG. 11A is a schematic cross-sectional view of a display panel 100a. The display panel 100a is different from the display panel 100 mainly in the structure of the light-emitting element and including a coloring layer.

The display panel 100a includes light-emitting elements 110W that emit white light. The light-emitting elements 110W each include the pixel electrode 111, an organic layer 112W, the common layer 114, and the common electrode 113. The organic layer 112W emits white light. For example, the organic layer 112W can contain two or more kinds of light-emitting materials whose emission colors are complementary colors. For example, the organic layer 112W can contain a light-emitting organic compound that emits red light, a light-emitting organic compound that emits green light, and a light-emitting organic compound that emits blue light. Alternatively, the organic layer 112W may contain a light-emitting organic compound that emits blue light and a light-emitting organic compound that emits yellow light.

The organic layer 112W is divided between two adjacent light-emitting elements 110W. Thus, leakage current flowing between the adjacent light-emitting elements 110W through the organic layer 112W can be inhibited and crosstalk due to the leakage current can be inhibited. Accordingly, the display panel can achieve high contrast and high color reproducibility.

An insulating layer 122 that functions as a planarization film is provided over the protective layer 121, and a coloring layer 116R, a coloring layer 116G, and a coloring layer 116B are provided over the insulating layer 122.

An organic resin film or an inorganic insulating film with a flat top surface can be used for the insulating layer 122. The insulating layer 122 is a formation surface on which the coloring layer 116R, the coloring layer 116G, and the coloring layer 116B are formed. Thus, with a flat top surface of the insulating layer 122, the thickness of the coloring layer 116R or the like can be uniform and color purity can be increased. Note that when the thickness of the coloring layer 116R or the like is non-uniform, the amount of light absorption varies depending on a place in the coloring layer 116R, which might decrease the color purity.

### Structure Example 3

FIG. 11B is a schematic cross-sectional view of a display panel 100b.

The light-emitting element 110R includes the pixel electrode 111, a conductive layer 115R, the organic layer 112W, and the common electrode 113. The light-emitting element 110G includes the pixel electrode 111, a conductive layer 115G, the organic layer 112W, and the common electrode 113. The light-emitting element 1101B includes the pixel electrode 111, a conductive layer 115B, the organic layer 112W, and the common electrode 113. The conductive layer 115R, the conductive layer 115G, and the conductive layer 115B each have a light-transmitting property and function as an optical adjustment layer.

A film that reflects visible light is used for the pixel electrode 111 and a film having a property of reflecting and transmitting visible light is used for the common electrode 113, so that a micro resonator (microcavity) structure can be achieved. In that case, by adjusting the thicknesses of the conductive layer 115R, the conductive layer 115G, and the conductive layer 115B to obtain optimal optical path length, light with different wavelengths and increased intensities can be obtained from the light-emitting element 110R, the light-emitting element 110G, and the light-emitting element 110B even when the organic layer 112 that emits white light is used.

Furthermore, the coloring layer 116R, the coloring layer 116G, and the coloring layer 116B are provided on the optical paths of the light-emitting element 110R, the light-emitting element 110G, and the light-emitting element 110B, respectively, so that light with high color purity can be obtained.

In addition, an insulating layer 123 that covers an end portion of the pixel electrode 111, an end portion of the conductive layer 115R, the conductive layer 115G, or the conductive layer 115B is provided. An end portion of the insulating layer 123 preferably has a tapered shape. When the insulating layer 123 is provided, coverage with the organic layer 112W, the common electrode 113, the protective layer 121, and the like provided over the insulating layer 123 can be increased.

The organic layer 112W and the common electrode 113 are each provided as one continuous film shared by the light-emitting elements. Such a structure is preferable because the manufacturing process of the display panel can be greatly simplified.

Here, the end portion of the pixel electrode 111 preferably has a substantially vertical shape. Accordingly, a steep portion can be formed on the surface of the insulating layer 123, and thus a thin portion can be formed in part of the organic layer 112W that covers the steep portion or part of the organic layer 112W can be divided. Accordingly, leakage current generated between adjacent light-emitting elements through the organic layer 112W can be inhibited without processing the organic layer 112W by a photolithography method or the like.

The above is the description of the structure example of the display panel.

### [Pixel Layout]

Pixel layout different from that in FIG. 10A will be mainly described below. There is no particular limitation on the arrangement of light-emitting elements (subpixels), and a variety of methods can be employed.

In addition, examples of a top surface shape of the subpixel include polygons such as a triangle, a tetragon (including a rectangle and a square), and a pentagon; polygons with rounded corners; an ellipse; and a circle. Here, the top surface shape of the subpixel corresponds to a top surface shape of a light-emitting region of the light-emitting element.

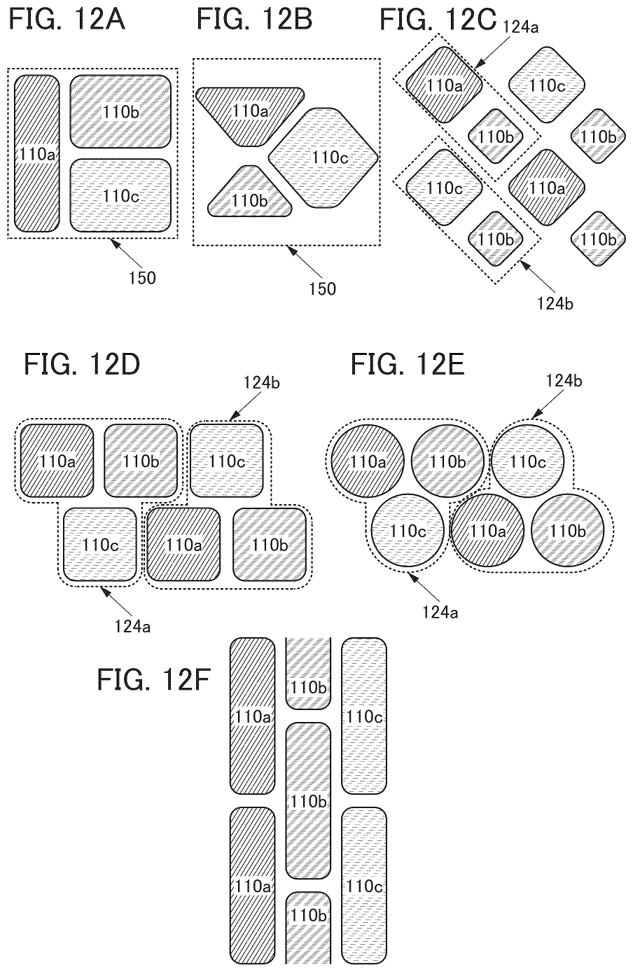

A pixel 150 illustrated in FIG. 12A employs an S-stripe arrangement. The pixel 150 illustrated in FIG. 12A is composed of three subpixels: light-emitting elements 110a, 110b, and 110c. For example, the light-emitting element 110a may be a blue-light-emitting element, the light-emitting element 110b may be a red-light-emitting element, and the light-emitting element 110c may be a green-light-emitting element.

The pixel 150 illustrated in FIG. 12B includes the light-emitting element 110a whose top surface has a rough trapezoidal or rough triangle shape with rounded corners, the light-emitting element 110b whose top surface has a rough trapezoidal or rough triangle shape with rounded corners, and the light-emitting element 110c whose top surface has a rough tetragonal or rough hexagonal shape with rounded corners. In addition, the light-emitting element 110a has a larger light-emitting area than the light-emitting element 110b. In this manner, the shapes and sizes of the light-emitting elements can be independently determined. For example, the size of a light-emitting element with higher reliability can be made smaller. For example, the light-emitting element 110a may be a green light-emitting element, the light-emitting element 110b may be a red light-emitting element, and the light-emitting element 110c may be a blue light-emitting element.

Pixels 124a and 124b illustrated in FIG. 12C employ a PenTile arrangement. FIG. 12C illustrates an example where the pixels 124a each including the light-emitting element 110a and the light-emitting element 110b and the pixels 124b each including the light-emitting element 110b and the light-emitting element 110c are alternately arranged. For example, the light-emitting element 110a may be a red light-emitting element, the light-emitting element 110b may be a green light-emitting element, and the light-emitting element 110c may be a blue light-emitting element.

The pixels 124a and 124b illustrated in FIG. 12D and FIG. 12E employ a delta arrangement. The pixel 124a includes two light-emitting elements (the light-emitting elements 110a and 110b) in an upper row (a first row) and one light-emitting element (the light-emitting element 110c) in a lower row (a second row). The pixel 124b includes one light-emitting element (the light-emitting element 110c) in the upper row (the first row) and two light-emitting elements (the light-emitting elements 110a and 110b) in the lower row (the second row). For example, the light-emitting element 110a may be a red light-emitting element, the light-emitting element 110b may be a green light-emitting element, and the light-emitting element 110c may be a blue light-emitting element.

FIG. 12D illustrates an example where the top surface of each light-emitting element has a rough tetragonal shape with rounded corners, and FIG. 12E illustrates an example where the top surface of each light-emitting element is circular.

FIG. 12F illustrates an example where light-emitting elements of different colors are arranged in a zigzag manner. Specifically, the positions of top sides of two light-emitting elements arranged in a row direction (e.g., the light-emitting element 110a and the light-emitting element 110b or the light-emitting element 110b and the light-emitting element 110c) are not aligned in a top view. For example, the light-emitting element 110a may be a red light-emitting element, the light-emitting element 110b may be a green light-emitting element, and the light-emitting element 110c may be a blue light-emitting element.

In a photolithography method, as a pattern to be processed becomes finer, the influence of light diffraction becomes more difficult to ignore; accordingly, fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a light-emitting element has a polygonal shape with rounded corners, an elliptical shape, a circular shape, or the like in some cases.

Furthermore, in a method for manufacturing a display panel according to one embodiment of the present invention, the EL layer is processed into an island shape with the use of a resist mask. A resist film formed over the EL layer needs to be cured at a temperature lower than the upper temperature limit of the EL layer. Thus, the resist film is insufficiently cured in some cases depending on the upper temperature limit of the material of the EL layer and the curing temperature of a resist material. An insufficiently cured resist film might have a shape different from a desired shape at the time of processing. As a result, a top surface of the EL layer has a polygonal shape with rounded corners, an elliptical shape, a circular shape, or the like in some cases. For example, when a resist mask with a square top surface is intended to be formed, a resist mask with a circular top surface might be formed, and the top surface of the EL layer might be circular.

Note that to obtain a desired top surface shape of the EL layer, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

The above is the description of the pixel layout.

Note that in the proximate mode described in Embodiment 1, it is preferable that high-definition display be performed by a display panel with a high pixel density since a large amount of information is to be displayed. Meanwhile, in the distant mode, high-definition display beyond the resolution of human eyes leads to waste in terms of rendering load and power consumption, because the user sees the display apart from the eyes. Thus, in the distant mode, it is preferable that display be performed with reduced definition even though a display panel with a high pixel density is used.

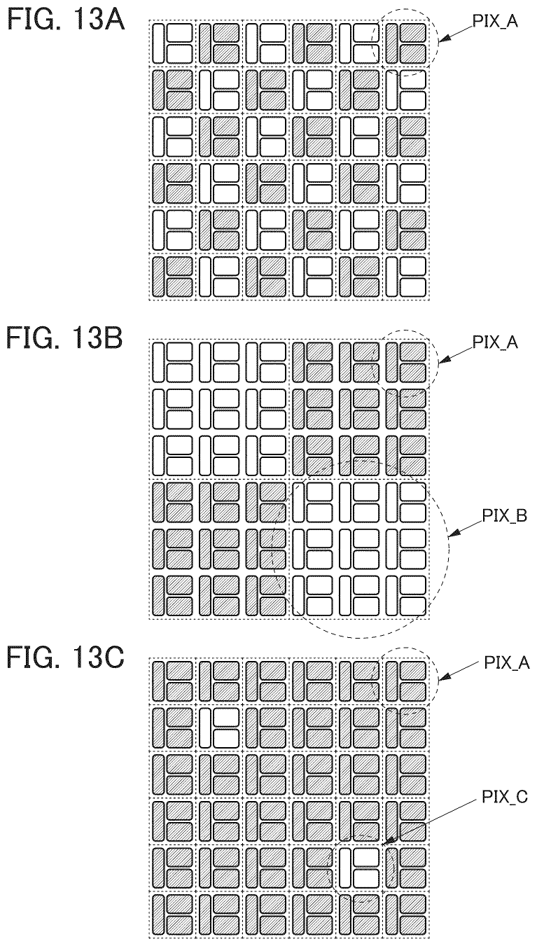

For example, it is preferable to perform driving in a way that individual image signals are input to each pixel PIX_A as illustrated in FIG. 13A in the proximate mode, and to perform driving in a way that PIX_B composed of multiple pixels PIX_A is collectively driven as illustrated in FIG. 13B in the distant mode.

Specifically, when the display panel is 3207 ppi (7.92 μm×7.92 μm per pixel), driving the 3×3 pixels PIX_A as one pixel PIX_B as illustrated in FIG. 13B enables the display panel to be used as a display panel with 1069 ppi (23.8 μm×23.8 μm per pixel). Driving 6×6 pixels PIX_A as one pixel PIX_B enables the display panel to be used as a display panel with 535 ppi (47.5 μm×47.5 μm per pixel). Such driving can reduce the rendering load.

Alternatively, it is preferable that the driving be performed in a way that image signals are input to only some of the pixels PIX_A (pixels PIX_C), as illustrated in FIG. 13C. Such driving can reduce power consumption because signal input to the pixels PIX_A that are not driven is unnecessary and those pixels PIX_A are not driven. Note that, in the case where the driving illustrated in FIG. 13C is performed, it is preferable that the pixels driven as the pixels PIX_C be shifted periodically to prevent burn-in.

Note that although FIG. 13A to FIG. 13C illustrate the pixel arrays each being made up of the pixels 150 illustrated in FIG. 13A as examples, similar driving is preferably performed even in the case where the other pixels described in this embodiment are used. In addition, area coverage modulation may be performed using a pixel composed of a plurality of pixels PIX_A.

At least part of this embodiment can be implemented in combination with the other embodiments and examples described in this specification as appropriate.

### Embodiment 3

In this embodiment, the other structure examples of a display panel which can be used for an electronic device of one embodiment of the present invention will be described.

The display panel of this embodiment has high definition. Specifically, the display panel is suitably used for display portions of wearable devices that can be worn on a head, such as devices for VR typified by a head-mounted display, and glasses-type devices for AR.

### [Display Module]

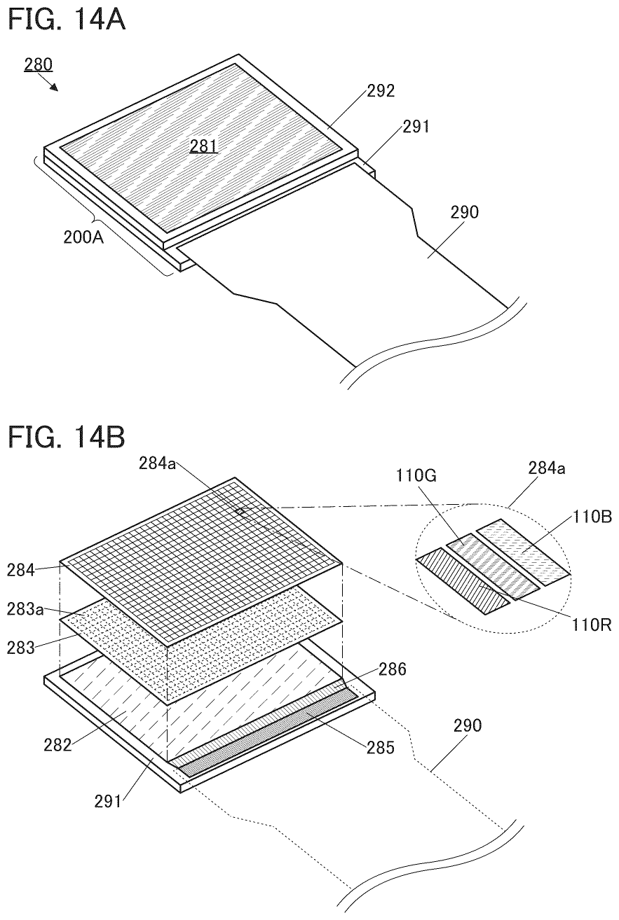

FIG. 14A is a perspective view of a display module 280. The display module 280 includes a display panel 200A and an FPC 290. Note that the display panel included in the display module 280 is not limited to the display panel 200A and may be any of display panels 200B to 200F to be described later.

The display module 280 includes a substrate 291 and a substrate 292. The display module 280 includes a display portion 281. The display portion 281 is a region where an image is displayed.

FIG. 14B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 14B. The pixel 284a includes a light-emitting element 110R emitting red light, the light-emitting element 110G emitting green light, and the light-emitting element 110B emitting blue light.

The pixel circuit portion 283 includes a plurality of pixel circuits 283a arranged periodically. One pixel circuit 283a controls light emission from three light-emitting devices included in one pixel 284a. One pixel circuit 283a may include three circuits each of which controls light emission from one light-emitting device. For example, the pixel circuit 283a can include at least one selection transistor, one current control transistor (driving transistor), and a capacitor for one light-emitting device. In this case, a gate signal is input to a gate of the selection transistor, and a source signal is input to a source of the selection transistor. Thus, an active matrix display panel is achieved.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like. A transistor included in the circuit portion 282 may constitute part of the pixel circuit 283a. That is, the pixel circuit 283a may be constituted by a transistor included in the pixel circuit portion 283 and a transistor included in the circuit portion 282.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have significantly high definition. For example, the pixels 284a are preferably arranged in the display portion 281 with definition higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high definition, and thus can be suitably used for a device for VR such as a head-mounted display or a glasses-type device for AR. For example, even in the case of a structure in which the display portion of the display module 280 is seen through a lens, pixels of the extremely-high-definition display portion 281 included in the display module 280 are prevented from being recognized when the display portion is enlarged by the lens, so that display providing a high sense of immersion can be performed. Without being limited thereto, the display module 280 can be suitably used for electronic devices including a relatively small display portion. For example, the display module 280 can be suitably used in a display portion of a wearable electronic device, such as a wrist watch.

### [Display Panel 200A]

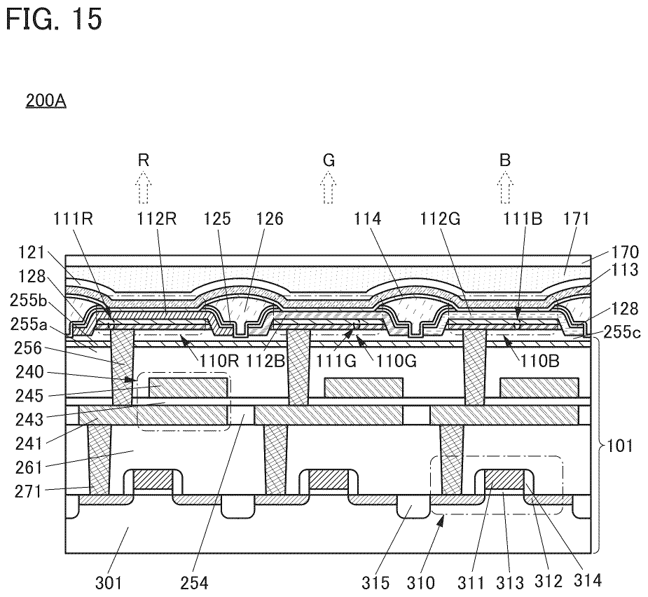

The display panel 200A illustrated in FIG. 15 includes a substrate 301, the light-emitting elements 110R, 110G, and 110B, a capacitor 240, and a transistor 310.

The substrate 301 corresponds to the substrate 291 in FIGS. 14A and 14B.

The transistor 310 includes a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the two. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of a source and a drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240, an insulating layer 255b is provided over the insulating layer 255a, and an insulating layer 255c is provided over the insulating layer 255b.

An inorganic insulating film can be suitably used as each of the insulating layers 255a, 255b, and 255c. For example, it is preferable that a silicon oxide film be used as the insulating layers 255a and 255c and a silicon nitride film be used as the insulating layer 255b. This enables the insulating layer 255b to function as an etching protective film. Although this embodiment describes an example where the insulating layer 255c is partly etched and a depressed portion is formed, the depressed portion is not necessarily provided in the insulating layer 255c.

The light-emitting element 110R which emits red light, the light-emitting element 110G which emits green light, and the light-emitting element 110B which emits blue light are provided over the insulating layer 255c. Embodiment 2 can be referred to for the structures of the light-emitting element 110R, the light-emitting element 110G, and the light-emitting element 110B.

In the display panel 200A, since the light-emitting devices of different colors are separately formed, the difference between the chromaticity at low luminance emission and that at high luminance emission is small. Furthermore, since the organic layers 112R, 112G, and 112B are separated from each other, crosstalk generated between adjacent subpixels can be inhibited while the display panel has high definition. Accordingly, the display panel can have high definition and high display quality.

In the region between adjacent light-emitting elements, the insulating layer 125, the resin layer 126, and the layer 128 are provided.

The pixel electrode 111R, the pixel electrode 111G, and the pixel electrode 111B are each electrically connected to one of the source and the drain of the transistor 310 through a plug 256 embedded in the insulating layers 255a, 255b, and 255c, the conductive layer 241 embedded in the insulating layer 254, and the plug 271 embedded in the insulating layer 261. The top surface of the insulating layer 255c and the top surface of the plug 256 are level with or substantially level with each other. Any of a variety of conductive materials can be used for the plugs.

The protective layer 121 is provided over the light-emitting elements 110R, 110G, and 110B. A substrate 170 is attached over the protective layer 121 with an adhesive layer 171.

An insulating layer covering an end portion of the top surface of the pixel electrode 111 is not provided between two adjacent pixel electrodes 111. Thus, the distance between adjacent light-emitting elements can be extremely narrowed. Accordingly, the display panel can have high definition or high resolution.

### [Display Panel 200B]

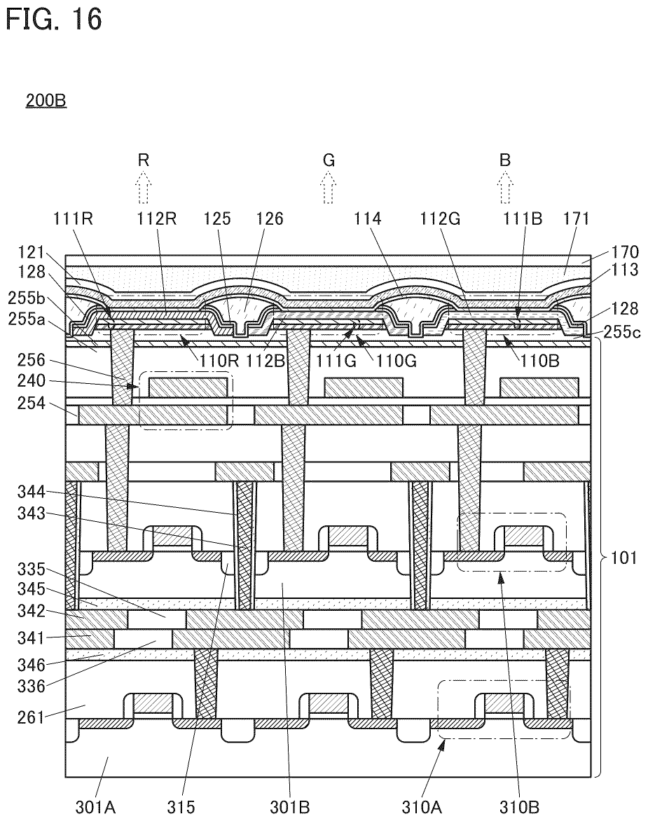

A display panel 200B illustrated in FIG. 16 has a structure in which a transistor 310A and a transistor 310B each having a channel formed in a semiconductor substrate are stacked. Note that in the following description of display panels, the description of portions similar to those of the above-described display panel may be omitted.

In the display panel 200B, a substrate 301B provided with the transistor 310B, the capacitor 240, and the light-emitting devices is attached to a substrate 301A provided with the transistor 310A.

Here, an insulating layer 345 is provided on the bottom surface of the substrate 301B. An insulating layer 346 is provided over the insulating layer 261 over the substrate 301A. The insulating layers 345 and 346 function as protective layers and can inhibit diffusion of impurities into the substrate 301B and the substrate 301A. As the insulating layers 345 and 346, an inorganic insulating film that can be used as the protective layer 121 can be used.

The substrate 301B is provided with a plug 343 that penetrates the substrate 301B and the insulating layer 345. An insulating layer 344 functioning as a protective layer is preferably provided to cover the side surface of the plug 343.

A conductive layer 342 is provided under the insulating layer 345 on the rear surface of the substrate 301B. The conductive layer 342 is embedded in an insulating layer 335. Bottom surfaces of the conductive layer 342 and the insulating layer 335 are planarized. The conductive layer 342 is electrically connected to the plug 343.

A conductive layer 341 is provided over the insulating layer 346 over the substrate 301A. The conductive layer 341 is embedded in an insulating layer 336. Top surfaces of the conductive layer 341 and the insulating layer 336 are planarized.

The conductive layers 341 and 342 are preferably formed using the same conductive material. For example, it is possible to use a metal film containing an element selected from Al, Cr, Cu, Ta, Ti, Mo, and W, or a metal nitride film containing any of the above elements as a component (a titanium nitride film, a molybdenum nitride film, or a tungsten nitride film). Copper is particularly preferably used for the conductive layers 341 and 342. In that case, it is possible to employ Cu—Cu (copper-to-copper) direct bonding (a technique for achieving electrical continuity by connecting Cu (copper) pads).

### [Display Panel 200C]

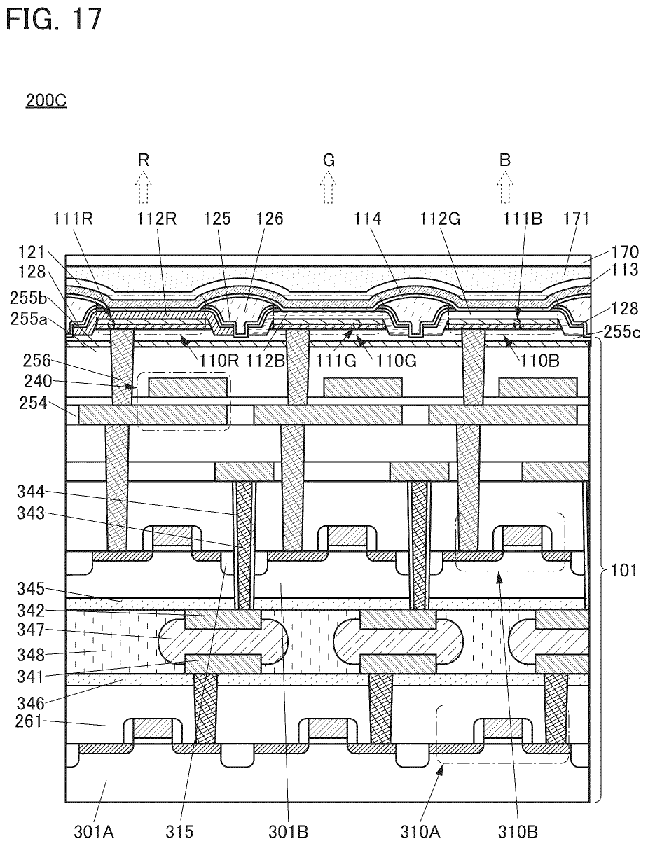

A display panel 200C illustrated in FIG. 17 has a structure in which the conductive layer 341 and the conductive layer 342 are bonded to each other with a bump 347.

As illustrated in FIG. 17, providing the bump 347 between the conductive layer 341 and the conductive layer 342 enables the conductive layers 341 and 342 to be electrically connected to each other. The bump 347 can be formed using a conductive material containing gold (Au), nickel (Ni), indium (In), tin (Sn), or the like, for example. As another example, solder may be used for the bump 347. An adhesive layer 348 may be provided between the insulating layer 345 and the insulating layer 346. In the case where the bump 347 is provided, the insulating layer 335 and the insulating layer 336 may be omitted.

### [Display Panel 200D]

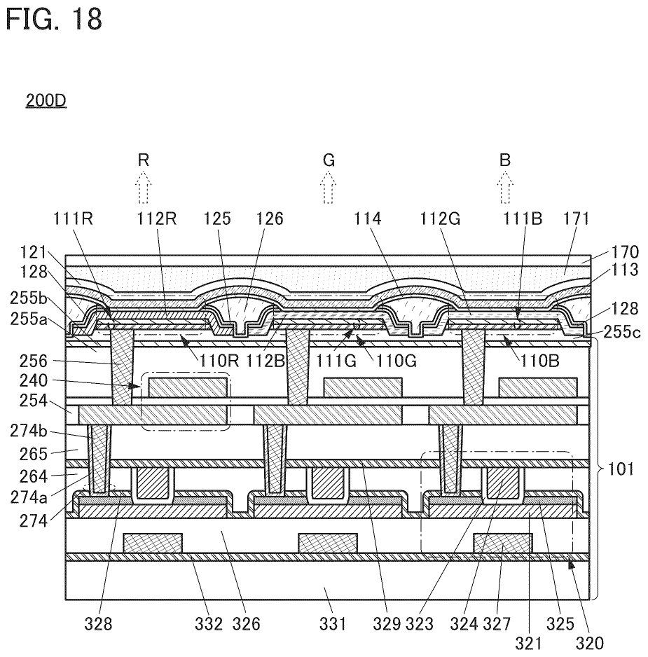

A display panel 200D illustrated in FIG. 18 differs from the display panel 200A mainly in a structure of a transistor.

A transistor 320 is a transistor that contains a metal oxide (also referred to as an oxide semiconductor) in a semiconductor layer where a channel is formed (i.e., an OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIGS. 14A and 14B.

An insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used for at least the part of the insulating layer 326 that is in contact with the semiconductor layer 321. The top surface of the insulating layer 326 is preferably planarized.

The semiconductor layer 321 is provided over the insulating layer 326. A metal oxide film having semiconductor characteristics (also referred to as an oxide semiconductor film) is preferably used as the semiconductor layer 321. The pair of conductive layers 325 is provided on and in contact with the semiconductor layer 321, and functions as a source electrode and a drain electrode.

An insulating layer 328 is provided to cover the top and side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water or hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layers 328 and 264. The insulating layer 323 that is in contact with the top surface of the semiconductor layer 321 and the conductive layer 324 are embedded in the opening portion. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that they are level with or substantially level with each other, and insulating layers 329 and 265 are provided to cover these layers.

The insulating layers 264 and 265 each function as an interlayer insulating layer. The insulating layer 329 functions as a barrier layer that prevents diffusion of impurities such as water or hydrogen from the insulating layer 265 or the like to the transistor 320. As the insulating layer 329, an insulating film similar to the insulating layers 328 and 332 can be used.

A plug 274 electrically connected to one of the pair of conductive layers 325 is provided to be embedded in the insulating layers 265, 329, and 264. Here, the plug 274 preferably includes a conductive layer 274a that covers the side surface of an opening formed in the insulating layers 265, 329, 264, and 328 and part of the top surface of the conductive layer 325, and a conductive layer 274b in contact with the top surface of the conductive layer 274a. For the conductive layer 274a, a conductive material in which hydrogen and oxygen are less likely to diffuse is preferably used.

There is no particular limitation on the structure of the transistors included in the display panel of this embodiment. For example, a planar transistor, a staggered transistor, or an inverted staggered transistor can be used. A top-gate transistor or a bottom-gate transistor can be used. Alternatively, gates may be provided above and below a semiconductor layer where a channel is formed.

The structure in which the semiconductor layer where a channel is formed is provided between two gates is used for the transistor 320. The two gates may be connected to each other and supplied with the same signal to drive the transistor. Alternatively, the threshold voltage of the transistor may be controlled by supplying a potential for controlling the threshold voltage to one of the two gates and supplying a potential for driving to the other of the two gates.

There is no particular limitation on the crystallinity of a semiconductor material used in the semiconductor layer of the transistor, and an amorphous semiconductor, a single crystal semiconductor, or a semiconductor having crystallinity other than single crystal (a microcrystalline semiconductor, a polycrystalline semiconductor, or a semiconductor partly including crystal regions) can be used. A single crystal semiconductor or a semiconductor having crystallinity is preferably used, in which case deterioration of the transistor characteristics can be inhibited.

The bandgap of a metal oxide used for the semiconductor layer of the transistor is preferably higher than or equal to 2 eV, further preferably higher than or equal to 2.5 eV. The use of such a metal oxide having a wide band gap can reduce the off-state current of the OS transistor.

A metal oxide preferably contains at least indium or zinc, and further preferably contains indium and zinc. The metal oxide preferably contains indium, M (M is one or more of gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example.

Alternatively, the semiconductor layer of the transistor may contain silicon. Examples of silicon include amorphous silicon and crystalline silicon (e.g., low-temperature polysilicon or single crystal silicon).

Examples of the metal oxide that can be used for the semiconductor layer include indium oxide, gallium oxide, and zinc oxide. The metal oxide preferably contain two or three kinds selected from indium, the element M, and zinc. The element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. Specifically, the element M is preferably one or more kinds selected from aluminum, gallium, yttrium, and tin.

Note that in the case where a metal oxide is used for the semiconductor layer, the metal oxide is preferably formed by a sputtering method or an ALD method. In the case where the metal oxide is formed by a sputtering method, the productivity and the film density can be increased. In the case where the metal oxide is formed by an ALD method, coverage with a film can be improved.

It is particularly preferable that an oxide containing indium, gallium, and zinc (also referred to as IGZO) be used as the metal oxide used for the semiconductor layer. Alternatively, it is preferable to use an oxide containing indium, tin, and zinc (also referred to as ITZO (registered trademark)). Alternatively, it is preferable to use an oxide containing indium, gallium, tin, and zinc. Alternatively, it is preferable to use an oxide containing indium, aluminum, and zinc (also referred to as IAZO). Alternatively, it is preferable to use an oxide containing indium, aluminum, gallium, and zinc (also referred to as IAGZO).

In the case where the metal oxide used for the semiconductor layer is an In-M-Zn oxide, the atomic proportion of In the is preferably higher than or equal to the atomic proportion of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of ±30% of a desired atomic ratio.

Gallium or tin is preferably used as the element M. Note that two or more of the above elements may be used in combination as the element M. For example, a metal oxide with In:M:Zn=40:1:10 or the neighborhood thereof is preferably used for the semiconductor layer. Specifically, a metal oxide with In:Sn:Zn=40:1:10 or the neighborhood thereof can be suitably used.

For example, when the atomic ratio is described as In:Ga:Zn=4:2:3 or a composition in the neighborhood thereof, the case is included where the atomic proportion of Ga is greater than or equal to 1 and less than or equal to 3 and the atomic proportion of Zn is greater than or equal to 2 and less than or equal to 4 with the atomic proportion of In being 4. In addition, when the atomic ratio is described as In:Ga:Zn=5:1:6 or a composition in the neighborhood thereof, the case is included where the atomic proportion of Ga is greater than 0.1 and less than or equal to 2 and the atomic proportion of Zn is greater than or equal to 5 and less than or equal to 7 with the atomic proportion of In being 5. Furthermore, when the atomic ratio is described as In:Ga:Zn=1:1:1 or a composition in the neighborhood thereof, the case is included where the atomic proportion of Ga is greater than 0.1 and less than or equal to 2 and the atomic proportion of Zn is greater than 0.1 and less than or equal to 2 with the atomic proportion of In being 1.

The semiconductor layer may include two or more metal oxide layers having different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being formed over the first metal oxide layer can be suitably employed. In particular, gallium or aluminum is preferably used as the element M.

Alternatively, a stacked-layer structure or the like of one selected from indium oxide, indium gallium oxide, and IGZO, and one selected from IAZO, IAGZO, and ITZO (registered trademark) may be used, for example.

As examples of the oxide semiconductor having crystallinity, a CAAC (c-axis-aligned crystalline)-OS, an nc (nanocrystalline)-OS, and the like are given.

An OS transistor has much higher field-effect mobility than a transistor containing amorphous silicon. In addition, the OS transistor has an extremely low leakage current between a source and a drain in an off state (the leakage current is also referred to as an off-state current), and charge accumulated in a capacitor that is connected in series to the transistor can be retained for a long period. Furthermore, the power consumption of the display panel can be reduced with the OS transistor.

To increase the emission luminance of the light-emitting device included in the pixel circuit, the amount of a current flowing through the light-emitting device needs to be increased. To increase the current amount, the source-drain voltage of a driving transistor included in the pixel circuit needs to be increased. An OS transistor has a higher breakdown voltage between a source and a drain than a Si transistor; hence, a high voltage can be applied between the source and the drain of the OS transistor. Thus, with use of an OS transistor as the driving transistor included in the pixel circuit, the amount of a current flowing through the light-emitting device can be increased, resulting in an increase in emission luminance of the light-emitting device.

Assuming that the transistor operates in a saturation region, a change in the amount of a current between the source and the drain, with respect to a fluctuation in the gate-source voltage, in the OS transistor is smaller than that in the Si transistor. Accordingly, when an OS transistor is used as the driving transistor in the pixel circuit, a current flowing between the source and the drain can be set minutely in accordance with a change in gate-source voltage; hence, the amount of a current flowing through the light-emitting device can be controlled. Consequently, the number of gray levels expressed by the pixel circuit can be increased.

Regarding saturation characteristics of a current flowing when a transistor operates in a saturation region, a current (saturation current) can flow more stably in an OS transistor than in a Si transistor even when the source-drain voltage gradually increases. Thus, with the use of an OS transistor as the driving transistor, a current can be made to flow stably through the light-emitting device, for example, even when a variation in current-voltage characteristics of the EL device occurs. In other words, when the OS transistor operates in the saturation region, the source-drain current hardly changes with an increase in the source-drain voltage; hence, the emission luminance of the light-emitting device can be stable.

As described above, with the use of an OS transistor as the driving transistor included in the pixel circuit, it is possible to achieve “reduction in power consumption”, “increase in emission luminance”, “increase in gray level”, “inhibition of variation in light-emitting devices”, and the like.

### [Display Panel 200F]

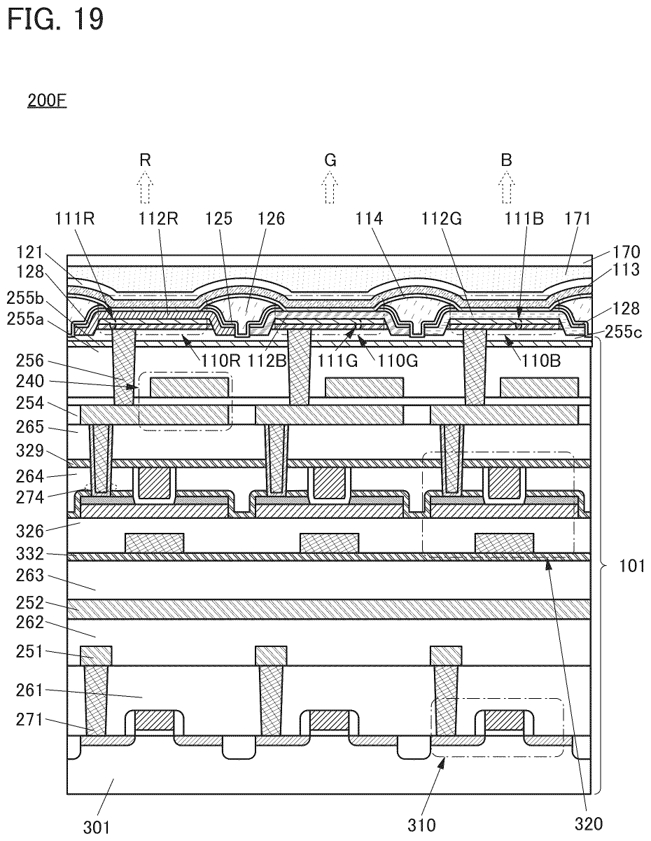

A display panel 200F illustrated in FIG. 19 has a structure in which the transistor 310 having a channel formed in the substrate 301 and the transistor 320 containing a metal oxide in a semiconductor layer where a channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit for driving the pixel circuit (a gate line driver circuit or a source line driver circuit). The transistor 310 and the transistor 320 can also be used as transistors included in a variety of circuits such as an arithmetic circuit and a memory circuit.

With such a structure, not only the pixel circuit but also the driver circuit and the like can be formed directly under the light-emitting devices; thus, the display panel can be downsized as compared with the case where a driver circuit is provided around a display region.

### [Display Panel 200G]

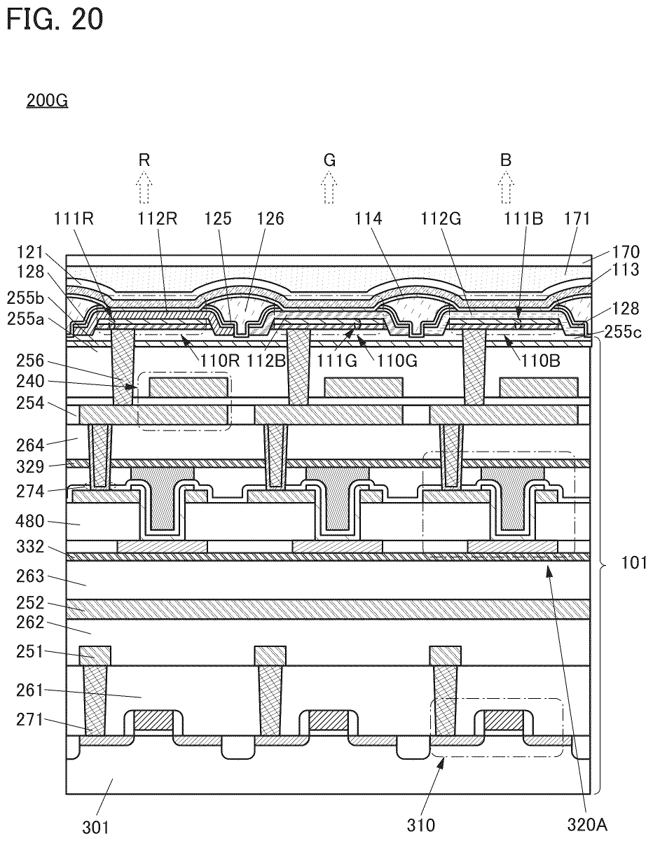

A display panel 200G illustrated in FIG. 20 has a structure in which the transistor 320 in the display panel 200F illustrated in FIG. 19 is replaced with a transistor 320A (vertical transistor). Note that the structure in which the transistor 320 is replaced with the transistor 320A can also be employed for the display panel 200D illustrated in FIG. 18.

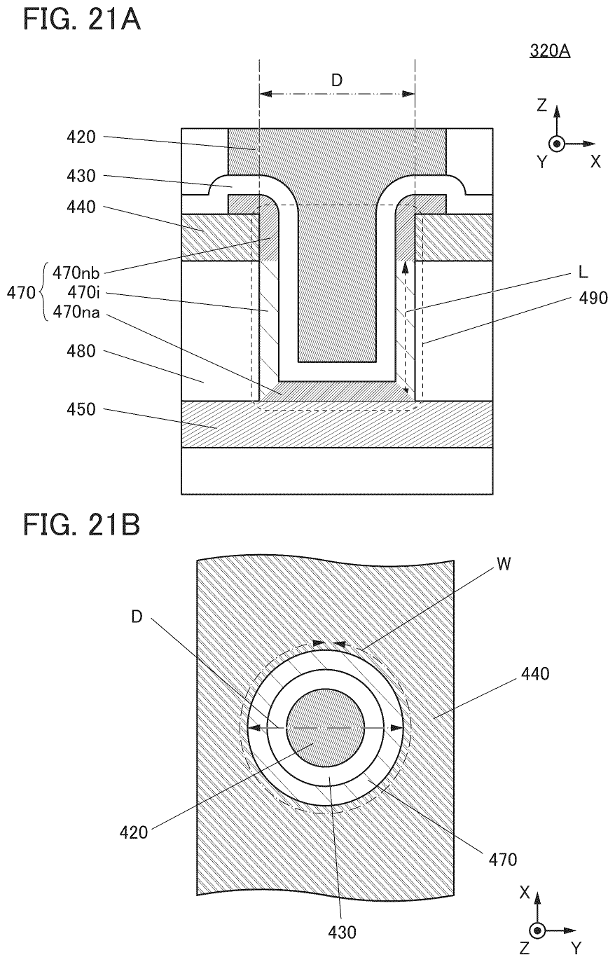

FIG. 21A is a cross-sectional view of the transistor 320A along the X-Z plane. FIG. 21B is a cross-sectional view along the X-Y plane including a wiring 440.

The transistor 320A includes an oxide semiconductor 470, an insulator 430, and a conductor 420. The oxide semiconductor 470 functions as a semiconductor layer, the insulator 430 functions as a gate insulator, and the conductor 420 functions as a gate electrode. A wiring 450 includes a region that functions as one of a source electrode and a drain electrode of the transistor 320A. The wiring 440 includes a region that functions as the other of the source electrode and the drain electrode of the transistor 320A.

An opening portion 490 penetrating through the wiring 440 and an insulator 480 and reaching the wiring 450 is provided. The opening portion 490 has a pillar shape with a substantially circular top surface. This structure enables miniaturization or high integration of the transistor. Note that the side surface of the opening portion 490 is preferably perpendicular to the top surface of the wiring 450.

At least part of the oxide semiconductor 470 is provided in the opening portion 490. Note that the oxide semiconductor 470 includes a region in contact with the top surface of the wiring 450, a region in contact with the side surface of the wiring 440, and a region in contact with the side surface of the insulator 480 in the opening portion 490.

The insulator 430 is provided so as to at least partly cover the opening portion 490. The conductor 420 is provided so that at least part of the conductor 420 is positioned in the opening portion 490. The conductor 420 is preferably provided so as to be embedded in the opening portion 490, and the top surface shape of the conductor 420 is preferably substantially circular for a higher integration degree.

As illustrated in FIG. 21A, the oxide semiconductor 470 includes a region 470i and regions 470na and 470nb provided with the region 470i positioned therebetween.

The region 470na is a region in contact with the wiring 450 in the oxide semiconductor 470. At least part of the region 470na functions as one of the source region and the drain region of the transistor 320A. The region 470nb is a region in contact with the wiring 440 in the oxide semiconductor 470. At least part of the region 470nb functions as the other of the source region and the drain region of the transistor 320A. As illustrated in FIG. 21B, the wiring 440 is in contact with all the perimeter of the oxide semiconductor 470. Thus, the other of the source region and the drain region of the transistor 320A can be formed along all the perimeter of a region formed in the same layer as the wiring 440 in the oxide semiconductor 470.

The region 470i is a region positioned between the region 470na and the region 470nb in the oxide semiconductor 470. At least part of the region 470i functions as the channel formation region of the transistor 320A. That is, the channel formation region of the transistor 320A is formed in part of the oxide semiconductor 470 that is positioned in a region between the wiring 450 and the wiring 440. It can be said that the channel formation region of the transistor 320A is positioned in a region in contact with the insulator 480 or a region in the vicinity thereof in the oxide semiconductor 470.

The channel length of the transistor 320A is a distance between the source region and the drain region. That is, the channel length of the transistor 320A is determined by the thickness of the insulator 480 over the wiring 450. In FIG. 21A, a channel length L of the transistor 320A is indicated by a dashed double-headed arrow. The channel length L is a distance between an end portion of a region where the oxide semiconductor 470 and the wiring 450 are in contact with each other and an end portion of a region where the oxide semiconductor 470 and the wiring 440 are in contact with each other in a cross-sectional view. That is, the channel length L corresponds to the length of the side surface of the insulator 480 on the opening portion 490 side in the cross-sectional view.

The channel length of a conventional transistor is set by the light exposure limit of photolithography. In contrast, in one embodiment of the present invention, the channel length can be determined by the thickness of the insulator 480. Thus, the transistor 320A can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm). Accordingly, the transistor 320A can have a high on-state current.

In addition, as described above, the channel formation region, the source region, and the drain region can be formed in the opening portion 490. Thus, the area occupied by the transistor 320A can be reduced as compared with a conventional transistor in which the channel formation region, the source region, and the drain region are provided separately on the X-Y plane. In addition, the pixel density can be increased.

The transistor including the channel formation region along the side surface of the insulator 480 in the opening portion 490 in the above-described manner is referred to as a vertical transistor.

Furthermore, in the X-Y plane including the channel formation region of the oxide semiconductor 470, as illustrated in FIG. 21B, the oxide semiconductor 470, the insulator 430, and the conductor 420 are provided concentrically. Therefore, the side surface of the conductor 420 provided at the center faces a side surface of the oxide semiconductor 470 with the insulator 430 therebetween. That is, in the top view, all the perimeter of the oxide semiconductor 470 serves as the channel formation region. In this case, for example, the channel width of the transistor 320A is determined by the length of the perimeter of the oxide semiconductor 470. In other words, the channel width of the transistor 320A is determined by the maximum width of the opening portion 490 (the maximum diameter in the case where the opening portion 490 is circular in the top view). In FIGS. 21A and 21B, a maximum width D of the opening portion 490 is indicated by a dashed double-dotted double-headed arrow. In FIG. 21B, a channel width W of the transistor 320A is indicated by a dashed-dotted double-headed arrow. By increasing the maximum width D of the opening portion 490, the channel width per unit area can be increased and the on-state current can be increased.

In the case where the opening portion 490 is formed by a photolithography method, the maximum width D of the opening portion 490 is set by the light exposure limit of photolithography. In addition, the maximum width D of the opening portion 490 is determined by the film thicknesses of the oxide semiconductor 470, the insulator 430, and the conductor 420 provided in the opening portion 490. The maximum width D of the opening portion 490 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 490 is circular in the top view, the maximum width D of the opening portion 490 corresponds to the diameter of the opening portion 490, and the channel width W can be “D×π”.

In the memory device of one embodiment of the present invention, the channel length L of the transistor 320A is preferably shorter than at least the channel width W of the transistor 320A. The channel length L of the transistor 320A in one embodiment of the present invention is greater than or equal to 0.1 times and less than or equal to 0.99 times, preferably greater than or equal to 0.5 times and less than or equal to 0.8 times the channel width W of the transistor 320A. This structure enables a transistor with favorable electrical characteristics and high reliability.

In the case where the opening portion 490 is formed to be substantially circular in the top view, the oxide semiconductor 470, the insulator 430, and the conductor 420 are formed concentrically. This makes the distance between the conductor 420 and the oxide semiconductor 470 substantially uniform, so that a gate electric field can be substantially uniformly applied to the oxide semiconductor 470.

It is preferable that the channel formation region of the transistor including an oxide semiconductor in the semiconductor layer contain fewer oxygen vacancies or have a lower concentration of an impurity such as hydrogen, nitrogen, or a metal element than the source region and the drain region. In some cases, hydrogen in the vicinity of an oxygen vacancy forms a defect that is an oxygen vacancy into which hydrogen enters (hereinafter sometimes referred to as V_{O}H), which generates an electron serving as a carrier. Thus, it is preferable that the amount of V_{O}H be also reduced in the channel formation region. Thus, the channel formation region of the transistor is a high-resistance region having a low carrier concentration. Accordingly, the channel formation region of the transistor can be regarded as an i-type (intrinsic) or substantially i-type region.

The source region and the drain region of the transistor including an oxide semiconductor in the semiconductor layer are regions which have lower resistances than the channel formation region by having increased carrier concentrations because of containing more oxygen vacancies or more V_{O}H or having higher concentrations of impurities such as hydrogen, nitrogen, or a metal element. In other words, the source region and the drain region of the transistor are n-type regions having higher carrier concentrations and lower resistances than the channel formation region.

Although the opening portion 490 is provided so that the side surface of the opening portion 490 is perpendicular to the top surface of the wiring 450 in FIG. 21A and the like, the present invention is not limited thereto. For example, the side surface of the opening portion 490 may have a tapered shape.

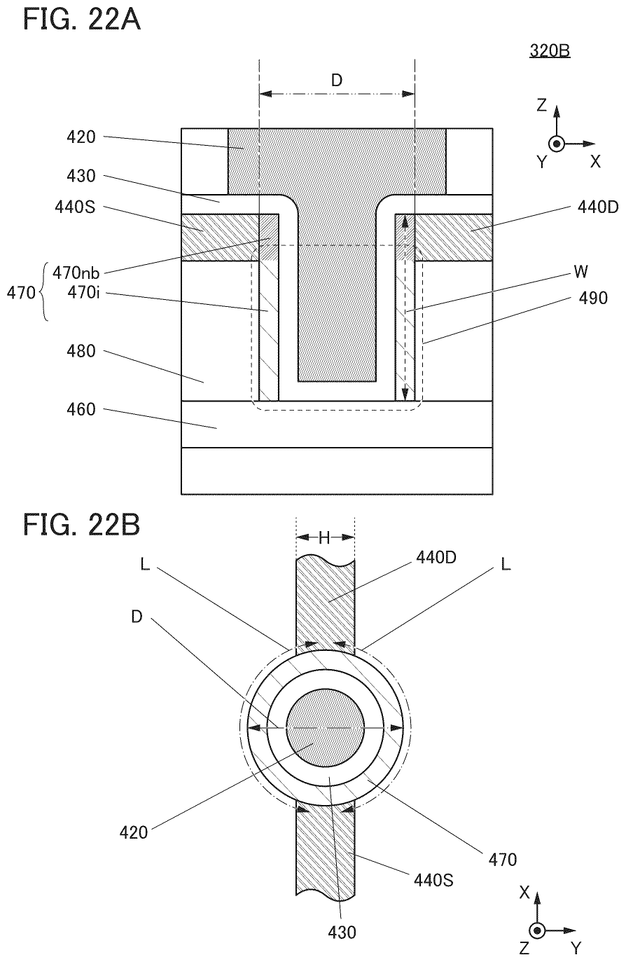

FIG. 22A illustrates a cross-sectional view of a transistor 320B, which is a vertical transistor having a structure different from that in FIG. 21, taken along an XZ plane. FIG. 22B is a cross-sectional view taken along an XY plane.

The transistor 320B is different from the transistor 320A mainly in that the wiring 450 is not included, the transistor is provided over the insulator 460, a wiring 440S and a wiring 440D are included instead of the wiring 440, and the shape of the oxide semiconductor 470 is different. The wiring 440S has a function of a source electrode, and the wiring 440D has a function of a drain electrode.

The oxide semiconductor 470 has a circular shape. Specifically, the oxide semiconductor 470 includes a region in contact with the side surface of the wiring 440S, a region in contact with the side surface of the wiring 440D, and a region in contact with the side surface of the insulator 480 in the opening portion 490. Here, the oxide semiconductor 470 is not in contact with the top surfaces of the wiring 440S and the wiring 440D. The oxide semiconductor 470 having such a shape can be formed by processing through anisotropic etching, for example.

As illustrated in FIG. 22B, the width H of the wiring 440S and the wiring 440D is smaller than the maximum width D of the opening portion 490. In that case, the circumferential direction of the opening portion 490 corresponds to the channel length direction of the transistor 320B. Here, since the oxide semiconductor 470 has a circular shape, there are two types of current paths (i.e., channels) from the wiring 440S to the wiring 440D. Note that the oxide semiconductor 470 does not have to have a circular shape and may have a structure in contact with both the wiring 440S and the wiring 440D.

The channel length can be controlled by the shape and size of the opening portion 490. In the case where the channel length is desired to be large, for example, the perimeter of the opening portion 490 is set long. Although this embodiment describes the example where the opening portion 490 has a circular shape in the plan view, the present invention is not limited thereto. For example, the opening portion 490 can have an elliptical shape or a quadrangular shape with rounded corners besides the circular shape in the plan view. Alternatively, a regular polygonal shape such as a regular triangular shape, a square shape, or a regular pentagonal shape or a polygonal shape other than the regular polygonal shape may be employed. By employing a concave polygonal shape in which at least one interior angle is greater than 180°, such as a star polygonal shape, the channel width can be increased. Alternatively, an elliptical shape, a polygonal shape with rounded corners, a closed curve in which a straight line and a curve are combined, or the like can be employed. In that case, the maximum width of the opening portion 490 is calculated as appropriate in accordance with the shape of the uppermost portion of the opening portion 490. For example, in the case where the opening portion is square or rectangular in the plan view, the maximum width of the opening portion 490 may be the length of a diagonal line of the uppermost portion of the opening portion 490.

As illustrated in FIG. 22A, the height of the oxide semiconductor 470 is the channel width W of the transistor 320B. Thus, the channel width W of the transistor 320B can be controlled by the thickness of the insulator 480. Thus, it is possible to make a very minute structure with the channel width of the transistor 320B being smaller than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm).

The transistor 320A is a transistor which has an extremely short channel length and can have a large channel width, and thus is capable of achieving a high on-state current. Meanwhile, the transistor 320B is a transistor which has an extremely small channel width and can have a large channel length, and thus is capable of achieving appropriate on-state current and the design thereof is easy. The transistor 320A and the transistor 320B can share part of the manufacturing process, and can each be formed over the same substrate. In a display device, for example, it is possible to use the transistor 320B as a driving transistor for controlling current flowing through a light-emitting element, and to use the transistor 320A as a transistor functioning as a switch.

At least part of this embodiment can be implemented in combination with the other embodiments and examples described in this specification as appropriate.

### REFERENCE NUMERALS

PIX_A: pixel, PIX_B: pixel, PIX_C: pixel, 10: electronic device, 11: case, 12: bezel, 13: dial window, 14: band, 20: eye, 30: display panel, 32: linear polarizing plate, 33: retardation plate, 41: element, 42: element, 45: optical unit, 52: layer, 53: retardation plate, 54: reflective polarizing plate, 70: pixel, 71: subpixel, 74: pixel array, 75: circuit, 76: circuit, 77: layer, 78: layer, 79: layer, 100a: display panel, 100b: display panel, 100: display panel, 101: substrate, 110a: light-emitting element, 110B: light-emitting element, 110b: light-emitting element, 110c: light-emitting element, 110G: light-emitting element, 110R: light-emitting element, 110W: light-emitting element, 110: light-emitting element, 111B: pixel electrode, 111C: connection electrode, 111G: pixel electrode, 111R: pixel electrode, 111: pixel electrode, 112B: organic layer, 112G: organic layer, 112R: organic layer, 112W: organic layer, 112: organic layer, 113: common electrode, 114: common layer, 115B: conductive layer, 115G: conductive layer, 115R: conductive layer, 116B: coloring layer, 116G: coloring layer, 116R: coloring layer, 121: protective layer, 122: insulating layer, 123: insulating layer, 124a: pixel, 124b: pixel, 125: insulating layer, 126: resin layer, 128: layer, 140: connection portion, 150: pixel, 170: substrate, 171: adhesive layer, 200A: display panel, 200B: display panel, 200C: display panel, 200D: display panel, 200F: display panel, 200G: display panel, 240: capacitor, 241: conductive layer, 243: insulating layer, 245: conductive layer, 251: conductive layer, 252: conductive layer, 254: insulating layer, 255a: insulating layer, 255b: insulating layer, 255c: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 420: conductor, 430: insulator, 440D: wiring, 440S: wiring, 440: wiring, 450: wiring, 460: insulator, 470i: region, 470na: region, 470nb: region, 470: oxide semiconductor, 480: insulator, 490: opening portion

1. An electronic device comprising:
a case;
a bezel comprising a reflective polarizing plate;
a display panel; and
an optical device,
wherein the display panel and the optical device are placed in a region surrounded by the case and the bezel,
wherein light emitted from the display panel is configured to be emitted through the optical device,
wherein the electronic device has a first mode in which display on the display panel is seen from a distance and a second mode in which display on the display panel is seen in proximity, and
wherein rotating the bezel enables switching is configured to switch between the first mode and the second mode.

2. The electronic device according to claim 1,
wherein the optical device comprises a first circular polarizing plate, a half mirror and a second circular polarizing plate,
wherein the half mirror is placed between the first circular polarizing plate and the second circular polarizing plate,
wherein the half mirror has a curved surface with a concave on a second circular polarizing plate side, and
wherein the second circular polarizing plate is included in the bezel.

3. The electronic device according to claim 2,
wherein the first circular polarizing plate comprises a linear polarizing plate and a first retardation plate, and
wherein the second circular polarizing plate comprises a second retardation plate and the reflective polarizing plate.

4. (canceled)

5. The electronic device according to claim 2,
wherein the half mirror is placed between a second component and a third component, and
wherein a difference between a refractive index of the second component and a refractive index of the third component is less than or equal to 0.3.

6. The electronic device according to claim 5, wherein each of a surface of the second component on a side opposite to a side with the half mirror and a surface of the third component on a side opposite to a side with the half mirror is a plane.

7. The electronic device according to claim 1, wherein a rotation angle of the bezel is 90°.

8. The electronic device according to claim 1, wherein the display panel comprises an organic EL element.

9. The electronic device according to claim 1, further comprising a dial window fixed to the bezel,
wherein light emitted from the display panel is configured to be emitted outside the electronic device through the optical device and the dial window.

10. A method for operating an electronic device,
wherein the electronic device is a watch-type electronic device comprising a display panel,
wherein the electronic device is capable of switching between a first mode enabling distant viewing and a second mode enabling proximate viewing,
wherein in the first mode drive is performed in which an image signal is input to some pixels included in the display panel, and
wherein in the second mode drive is performed in which an image signal is input to every pixel included in the display panel.

11. The method for operating an electronic device according to claim 10, wherein switching between the first mode and the second mode is performed by rotating a component of an optical device fixed to a bezel.

12. The electronic device according to claim 1, wherein the electronic device is a watch-type.
